(19) United States
(12) Patent Application Publication
(10) Pub. No.: US 2011/0089380 A1
(43) Pub. Date: Apr. 21, 2011

(54) Fullerene Multi-Adduct Compositions

(75) Inventors: Jan C. Hummelen, Groningen (NL); Floris Berend Kooistra, Groningen (NL); David F. Kronholm, Groningen (NL)

(73) Assignee: Solenne BV

(21) Appl. No.: 12/679,387

(22) PCT Filed: Sep. 22, 2008
(86) PCT No.: PCT/US08/77208

§ 371 Date: Dec. 21, 2010

Related U.S. Application Data
(60) Provisional application No. 60/974,360, filed on Sep. 21, 2007.

(51) Int. Cl. H01B 1/12; C07C 69/712; C07C 69/616; B82Y 30/00

(52) U.S. Cl. 252/500; 560/56; 560/8; 977/734; 977/735

(57) ABSTRACT

One aspect of the invention relates to compositions comprising one or more fullerene derivatives that comprise one or more covalent addends. In certain embodiments, the fullerene derivatives are selected from the group consisting of methanofullerene derivatives, Prato adduct fullerene derivatives, Diels-Alder fullerene derivatives, diazoline fullerene derivatives, Bingel fullerene derivatives, ketolactam fullerene derivatives, and azafulleroid fullerene derivatives. In certain embodiments, the fullerenes are C60 or C70 or a mixture thereof. The invention also relates to semiconductors, photodiodes, solar cells, photodectectors, and transistors comprising one or more fullerene derivatives that comprise one or more covalent addends.

### RELATED APPLICATIONS

This application claims the benefit of priority to U.S. Provisional Patent Application Ser. No. 60/974,360, filed Sep. 21, 2007; the entirety of which is hereby incorporated by reference.

### BACKGROUND OF THE INVENTION

Progress has been made in the field of organic photovoltaics, however increase in power conversion efficiency (η) is still a goal of development. One method to increase η is through variation and optimization of materials, for example, the N-type semiconductor. The devices made to date with the highest η use fullerene derivatives, typically Phenyl-C61-Butyric-Acid-Methyl-Ester ([60]PCBM) or Phenyl-C71-Butyric-Acid-Methyl-Ester ([70]PCBM) as the N-type semiconductor, blended with a P-type polymer in the bulk heterojunction configuration (for a general description, see Scharber, M. C. et al., Adv. Mater. 2006, 18, 789-794.). Fullerene derivatives have desirable properties for this application, including fast forward electron transfer relative to the back transfer rate, solution processability, and good electron mobilities.

η is a function of open-circuit voltage (VOC) as well as fill factor and short-circuit current, and variations in materials and/or processing conditions that lead to increases in VOC lead to higher η values, if fill factor and short-circuit current remain steady, or are reduced by a factor less than the increase in VOC. VOC in turn has been shown to be a function of the HOMO of donor (P-type) and LUMO of acceptor (N-type) (Kooistra, F. B., et al, Organic Letters, (9), 4, pp 551-554, 2007), and better matching between LUMO level of the acceptor and the HOMO of donor is desired to maximize the VOC. In almost all common P-type materials used to date, an increase in the LUMO of the acceptor is desired to achieve better matching with the HOMO of the P-type and thus an increase in VOC.

Alterations in LUMO of a fullerene derivative however is difficult while maintaining electron mobilities (which is a strong factor in determining the short circuit current) and other properties, like sufficient solubility to allow solution processing (Kooistra, F. B., et al, Organic Letters, (9), 4, pp 551-554, 2007). Therefore, fullerene derivatives wherein the LUMO has been increased relative to the LUMO of [60]PCBM and [70]PCBM (the LUMO of [70]PCBM is essentially the same as [60]PCBM), which maintain adequate electron mobilities, solubilities, and other properties are needed.

In organic electronics applications other than organic photovoltaics, such as, but not limited to: photodetector devices, transistors, and non-linear optics applications it may be desired to incorporate an N-type with a LUMO higher relative to [60]PCBM and [70]PCBM. Fullerenes higher in molecular weight than C70 have lower LUMO's than C60 and C70 and in some cases it may be desired to tune the LUMO of these higher fullerenes higher in order to obtain intermediate values, such as would lie between a C70 derivative and a C84 derivative.

Previously, an increase in LUMO relative to [60]PCBM was accomplished in Kooistra, F. B., et al, Organic Letters, (9), 4, pp 551-554, 2007, for several compounds by addition of methoxy groups to the phenyl of [60]PCBM. However, the increase in LUMO for the molecule that showed the highest increase relative to [60]PCBM was only ˜44 meV higher than [60]PCBM, and most of the molecules synthesized had inadequate solubility (and hence reduced processability), in addition to being more complex to synthesize than [60]PCBM.

Previously, mixtures of multi-adduct fullerene derivatives were tested in organic photovoltaics (Gebeyehu, D., Synthetic Metals, 118, pp 1-9, 2001), wherein the mixture tested consisted of mono-adduct, bis-adduct, and tris-adducts of [60]PCBM. This multi-adduct mixture was a by-product of the normal synthesis procedure of [60]PCBM. No specifications were given on the composition tested with respect to the various relative amounts of mono-, bis-, and tris-, adducts, and the mixture was found to give poor results in the organic photovoltaic devices tested. Also, no measurements or discussion of LUMO levels of the various compounds were reported.

Additionally, a composition comprising mixed isomers of a bis-indene C60 derivative was tested in an organic photovoltaic device. See WO 2008/018931. The bis-indene C60 derivative was characterized as “approximately 95%” in purity. The identities of the impurities were not specified, and the purity level of the starting C60 or C70 compositions used in the synthesis of the derivative were not reported. Moreover, no measurement or discussion of reduction potential or LUMO level, or desired impurity levels, was provided for this composition.

The hypothetical possibility of using a broad range of multi-adducts of a fullerene derivative in an organic photovoltaic active layer was mentioned in WO 2004/073082. However, the publication makes no mention of necessary impurities or the amounts that might be desirable in the compositions, variation in LUMO levels of different numbered adducts, or the projected impact on the open circuit voltage of the device.

There is a need also for new N-types, which in addition to having more desirable electronic properties (higher LUMO and adequate electron mobilities), have desirable solubility in organic solvents and also good miscibility with the P-type leading to a desired morphology. Morphology is a strong determiner of organic electronic device performance, and can be successfully altered by variations in the solubility of the N-type. Especially when used with polythiophenes in a bulk heterojunction configuration, de-mixing of the N-type and P-type is observed, and strategies to obtain more desirable morphologies have included the use of additives.

Zheng et al. (J. Phys. Chem. B 2004, 108 (32), 11921-11926) described results of varying the solubility of the N-type relative to [60]PCBM with the extension of alkyl chains at the ester, to alter morphology and improve processability. However, an increase in the alkyl chain showed diminished performance, as it is possible that electron mobilities were reduced due to an increase in the ball-to-ball lattice distances in the fullerene derivative crystal structure present in the device film. Therefore, N-type compounds which have altered solubility and/or miscibility, but while preserving the inherent properties of the native fullerene are desired for control of morphology, either used as the N-type, or used as an additive to a P-type/N-type system, wherein the additive enhances or alters the miscibility or otherwise alters the precipitation behavior of the N-type relative to the P-type. New compounds which may serve only to affect the blending and precipitation of the P-type/N-type system, and which are not active as the N-type are also desired. It is desired that such compounds would have compact addend structures relative to the C60, that is, addend moieties that are not overly large relative to the fullerene, to preserve electron mobility in the crystal of the fullerene derivative in the device film.

Finally, fullerene derivatives are useful as N-type semiconductors, also as ambipolar semiconductors, and for other uses, such as for radical scavenging in biological applications, polymer additives (to alter physical or electronic properties), and other uses known in the art.

### SUMMARY OF THE INVENTION

It is the object of the present invention to provide compositions and compounds of fullerene derivatives which may be useful as N-type or ambipolar semiconductors, and which have other uses as are known in the art for fullerenes, such as radical scavenging in biological applications, polymer additives (to alter physical or electronic properties), and other uses known in the art.

### BRIEF DESCRIPTION OF THE FIGURES

FIG. 1 depicts representative reaction products of Scheme 1. Macrocycles from 2 to more than 40 fullerene units and higher are also formed.

FIG. 2 depicts a cyclic Voltametry measurement performed on PCBM (solid line) and bisPCBM (dashed line).The inset shows the generalized chemical structure of the bisPCBM regio-isomers (i.e., the bottom addend is attached in a cyclopropane manner at various [6,6] positions, relative to the top one).

FIG. 3 depicts a plot of current density versus voltage, corrected for built in voltage and series resistance of a bisPCBM electron only device. Data (symbols) is fitted (solid line) using a space charge limited current with a field dependent mobility.

FIG. 4 depicts a plot of the external quantum efficiency of a P3HT:PCBM and P3HT:bisPCBM solar cell.

FIG. 5 depicts a plot of current density versus voltage of P3HT:PCBM and P3HT:bisPCBM solar cells under illumination of a 1000 W/m² halogen lamp.

FIGS. 6a-d show MALDI-TOF spectra for three types of pearl-necklace macrocycles based on co-polymers of bis-PCBM with 1,2-ethanediol, 1,4-butanediol, and 1,6-hexanediol, respectively. a) n=1; b) n=2; c) n=3; d) n=3: obtained from the reaction of depicted in scheme 3.

FIG. 7 shows the structures of possible intermediates formed during the synthesis of fullerene macrocycles and their corresponding masses.

FIG. 8 depicts an HPLC spectrum of bis-[60]PCBM prepared and used in Example 1. The three peaks visible in the absorption spectrum (top graph), correspond to three major regio-isomers of bis-[60]PCBM. No mono-adduct or tris-adduct is detectable in the HPLC top graph, indicating less than 0.1 mol % in the composition.

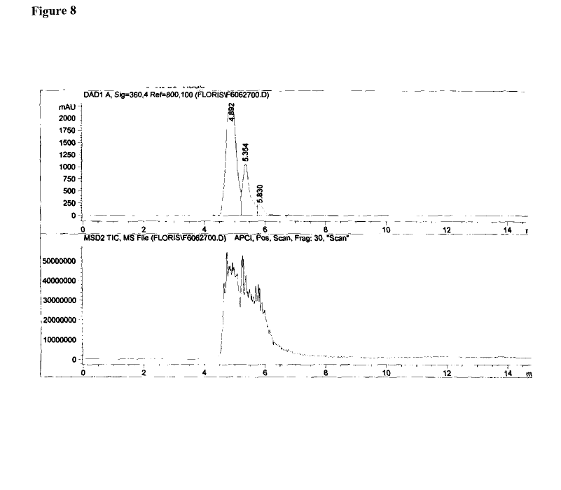

FIG. 9 depicts the HPLC spectrum of the bis-[70]PCBM used to obtain the 1^{st} reduction potential in Example 3. The levels of mono-adduct ([70]PCBM) and tris-adduct tris[70]PCBM are below 0.1% each.

FIG. 10 shows the synthetic scheme for the preparation of 3,4-OMe-[60]PCBM monoadduct, and bis-, tris-, and tetra-adducts.

FIG. 11 shows the synthetic scheme for the preparation of mixed methanofullerene compounds mono-Methoxy-mono-PCBM and mono-Methoxy-bis-PCBM.

FIG. 12 shows the synthetic scheme for [60]PCBM bis-adducts and tris-adducts.

FIG. 13 shows the synthetic scheme for the preparation of [70]PCBM bis-adducts and tris-adducts.

FIGS. 14a and 14b show the DPV results for a) [60]PCBM, bis[60]PCBM, tris[60]PCBM; and b) C₆₀, Methoxy, mono-Methoxy-mono-PCBM, and mono-Methoxy-bis-PCBM. The peak at approximately 0.3 V corresponds to the reference, ferrocene.

### DETAILED DESCRIPTION OF THE INVENTION

The compositions of the present invention make use of the properties of multi-adducts of fullerenes. Multi-adduct fullerene derivatives are commonly formed during synthesis of fullerene derivatives, typically in the form of mixtures of bis-adducts, tris-adducts, and lesser amounts of tetra- and higher multi-adducts, since usually they are desired to be minimized, for example by the use of minimal equivalents of addition reaction products. The multi-adducts (bis- and higher) are typically found in the form of regio-isomers due to the symmetry of fullerenes.

The compositions of the present invention are substantially pure in a given adduct number, such as substantially pure bis-adduct, substantially pure tris-adduct, substantially pure tetra-adduct, substantially pure penta-adduct, substantially pure hexa-adduct, and substantially pure adducts of higher number. It has been discovered that addition of multiple adducts (where here we take n as the number of adducts) may have an effect in increasing the LUMO value of the fullerene derivative relative to the derivative with lesser adducts. In other words, many fullerene derivatives with n+1 adducts have a LUMO higher than the same derivative with n adducts, due to the disruption in the π-system of the fullerene ball. The effect of increasing the LUMO with multiple addends works in general provided that the addend moieties are not, for example, very strongly electron withdrawing, or extremely stabilizing of the fullerene anion, such as addends which consist of cationic groups, for example N-alkylated Prato adducts as are known in the art.

However, since the LUMO values differ for different number of n, it is important that each given N-type composition is pure below certain tolerance levels in derivatives which have differing n, as compounds with different LUMO levels could act as electron traps or hole traps in the device. Electron traps occur when compounds are present as impurities (i.e., impurities may refer to compounds present in amounts below the percolation threshold, which for example for C60 is theoretically 17%) that have a lower LUMO relative to the main component. Hole traps occur when compounds are present as impurities (i.e., impurities may refer to compounds present in amounts below the percolation threshold, which for example for C60 is theoretically 17%) that have a higher LUMO relative to the main component. Other compounds, such as underivatized fullerenes, unreacted fullerenes or fullerene derivatives higher in molecular weight than the fullerene derivative multi-adduct desired for the given application, or other compounds with a significantly different LUMO than the main compound must also be kept below a certain concentration for adequate performance in organic electronics applications. Compounds that act as electron traps may have a different tolerance level than compounds that act as hole traps. The relative difference in LUMO level can give rise to different tolerance levels as well. For example, if Compound 1, has a higher difference in LUMO to the main component than Compound 2, which has a lower difference in LUMO relative to the main component, then the tolerance level of Compound 1 may be less than Compound 2, since it is a stronger electron or hole trap. Likewise for hole traps.

It has been found that the substantially pure bis-adduct of [60]PCBM (bis-[60]PCBM), has a LUMO value which is ˜100 meV higher than [60]PCBM, but still maintains adequate electron mobilities, and has good solubility and processability in common organic electronics applications. The VOC of an organic photovoltaic device, where P3HT was used as the P-type processed by the solvent annealing technique (G. Li, et al., Nat. Mater. 4, 864 (2005).ref.) as is well known in the art, is approximately 0.15 V higher than a device incorporating [60]PCBM, processed similarly, and gives an η, as verified under standard test conditions, of 4.5%, compared to 3.8% for the cell made under identical conditions using [60]PCBM. Therefore, by replacing [60]PCBM with the substantially pure bis-[60]PCBM, cell performance was improved by a factor of 1.2, which is a very significant increase, and for P3HT, the substantially pure bis-[60]PCBM is clearly a more suitable electron acceptor in this system due to the better matching with the HOMO of the P-type. Due to the higher LUMO, bis-[60]PCBM provides better donor HOMO to LUMO acceptor matching for a variety of different P-type compounds, and in different device configurations, and under different processing conditions. It should be noted also that this performance increase is only seen when the concentration levels of the mono-adduct and tris-adduct are below a certain level. In this case, the concentration levels were about 0.1 mol % of the N-type composition. Though, the levels of the mono-adduct and tris-adduct could also be higher, and could be different, and adequate device performance obtained. It is critical that compounds of varying LUMO level with respect to the main component, which in the above case was bis-[60]PCBM, are present in the composition at levels less than a threshold where the compounds of varying LUMO may act as traps. This is typically less than about 20 mol %, but could be as low or lower than about 0.1 mol % with respect to the total fullerene composition. C60 and C70 have almost identical LUMOs, and thus do not act as electron traps for each other. However, [60]PCBM and tris-[60]PCBM, since they have significantly different LUMOs than bis-[60]PCBM, should be present in levels less than about 20%, and may be as low as about 0.1%, for best performance. Also, unreacted C76, C78, and C84 and fullerenes higher in molecular weight than these, as well as any mono- or multi-adduct derivatives of these, may also act as electron or hole traps, depending on the main component, since they have significantly lower LUMOs than C60 and C70 and derivatives of C60 and C70, and it is desirable when the main component is a C60 or C70 derivative that C76, C78, and C84 and fullerenes higher in molecular weight than these be present in levels less than 20 mol %, or more preferably less than 0.1 mol %. Unreacted C60 or C70 may be present in some cases where the main component is a multi-adduct of C60 and/or C70, in levels as high as about 20%, though in other cases, may be present in levels less than about 10 mol %, or less than about 0.1 mol %.

Compositions described herein may also include compounds not mentioned here, as long these compounds are not significant electron or hole traps.

Levels for [70]PCBM and tris-[70]PCBM in the example described above are similar to the levels desired for [60]PCBM and tris-[60]PCBM described above, and this is the case in general as the LUMO levels of [60] and [70] derivatives may be relatively similar when the addend moiety and the number of addend moieties is the same.

The multi-adduct compositions described herein may be mixtures of C60 and C70 derivatives, as described in Patent Application PCT/US07/72965 (which is hereby incorporated by reference in its entirety), such as a mixture of bis-[60]PCBM and bis-[70]PCBM, wherein levels of mono-adduct [60]PCBM and [70]PCBM and tris- and higher adducts of C60 and C70, as well as unreacted fullerenes, are controlled to within tolerance levels as described above.

Compositions of tris-[60]PCBM, wherein the concentration levels of compounds of different LUMO, such as [60]PCBM, bis-[60]PCBM, multi-adducts with 4 or more addends, and unreacted fullerenes, to varying degrees, depending on the LUMO of the fullerene, are envisioned to similarly have desirable electronic and physical properties for us as a semiconductor, as are substantially pure tetra-adducts, penta-adducts, hexa-adducts, and higher adducts (than hexa-) due to the increase in LUMO value obtained by each subsequent addition of an adduct. Roughly, addition of a PCBM adduct may increase LUMO by about 100 meV, though depending on the particular fullerene, multi-adduct and application, other properties, such as electron mobility, may be affected adversely.

Likewise, compositions of tetra-, penta-, or hexa-adducts or higher, wherein the various species which have a lower LUMO are controlled to within limits as outlined above, are also envisioned.

Multi-adducts of fullerenes, wherein the adduct is formed by addition chemistries other than diazolkane addition (which is normally used to make PCBMs) are also envisioned, and are well known in the art. For example, as described in PCT/US07/72965 (which is hereby incorporated by reference in its entirety), the Prato reaction, used to form fulleropyrrolidines, otherwise known as Prato adducts, may be used to form multi-adduct Prato adducts. The various chemistry techniques described in PCT/US07/72965 (which is hereby incorporated by reference in its entirety) may be used to form multi-adduct Diels-Alder fullerene derivatives, multi-adduct diazoline derivatives, multi-adduct Bingel derivatives, multi-adduct ketolactams, or multi-adduct azafulleroids, all of which are described in PCT/US07/72965 (which is hereby incorporated by reference in its entirety). The concept of multi-adduct fullerene derivatives offering the ability to conveniently alter LUMO however is not limited to the derivatives described above, but is a general feature of fullerenes, due to the electronic structure of the fullerene cage.

The multi-adducts of the present invention are present commonly in the form of regio-isomer mixtures, where for example the bis-adduct is present in the form of several regio-isomers, resulting from addition of the second adduct at differing positions on the fullerene relative to the first adduct. Different molecular weight fullerenes, such as C84 also are typically used as mixtures of isomers, and so such fullerenes lead to a more complex mixture of multi-adduct fullerene derivatives.

Fullerenes, being symmetric, with a relatively high number of reactive double bonds, when used in addition reactions to form fullerene derivatives, readily form multi-adducts.

The multi-adducts of the present invention are easily obtained by using the similar synthesis as used for the mono-adduct, however in some cases optimized through the use of higher equivalents of addition reactant to increase the yield of multi-adducts. Multi-adducts are commonly purified from the mono-adduct in fullerene syntheses, for example through the use of column chromatography using silica gel as the stationary phase and toluene, chloroform, chlorobenzene, ortho-dichlorobenzene, or other common fullerene solvents. Likewise, such column chromatography may be used to prepare the compositions of the present invention by altering concentrations of mono-adducts, bis-adducts, tris-adducts, tetra-adducts, penta-adducts, hexa-adducts and adducts with more than 6 addends, as required to prepare the desired composition.

Other methods of preparation may be used, such as crystallization, as the mono-, bis-, tris-, and higher adducts have significantly different solubilities. In the case where the addend provides additional solubility to the native fullerene, the more addends, the more soluble the derivative. Alternatively, if the addend reduces solubility, the higher number adducts are less soluble than the lower number adducts.

HPLC, activated carbon adsorption, chromatography, or filtration; complexation, and other methods may also be used to separate the different numbered adduct components and produce the compositions described herein.

An advantage of many of the multi-adduct compositions described herein is that they are formed in the typical synthetic procedures for fullerene derivatives. The relative amounts of mono-, bis-, tris-, and other multi-adducts can be optimized by increase in the equivalents of addition reactant, variation in temperature, or other routine reaction conditions optimization as is well known in the art.

In some instances, the invention described herein may comprise multi-adducts where the individual constituent addends on a given molecule are different, such as a [60]PCBM which has been further reacted by oxidation to form one or more epoxide units in addition to the PCBM addend. In some instances, it may be preferable, to synthesize and isolate the mono-adduct or multi-adduct of a fullerene, and then further react under appropriate reaction conditions, however, in some cases no intermediate isolation of the mono-adduct or multi-adduct is necessary. In the instances of this invention where the multi-adduct is comprised of more than one type of addend, the general rules of limiting compounds with lower or higher LUMO value, which varies depending on number and type of fullerene addend, are the same as outlined above.

Further, it has been found that multi-adduct fullerene derivatives can be used as a precursor to the synthesis of polymer compounds which have a macrocyclic structure, for example via transesterification of bis-[60]PCBM with the use of dibutyl tin oxide as catalyst with diols as shown in Scheme 1. Transesterification as shown in Scheme 1 is well known in the art, and reference to synthetic techniques can be found in Example 2 of this document.

These macrocyle polymer compounds exhibit excellent solubility and are useful as a new class of organic semiconductor, or as an additive in organic electronics applications to desirably alter thin film morphology for example, or for other applications where fullerenes are known to have use, such as but not limited to semiconductors or radical scavenging.

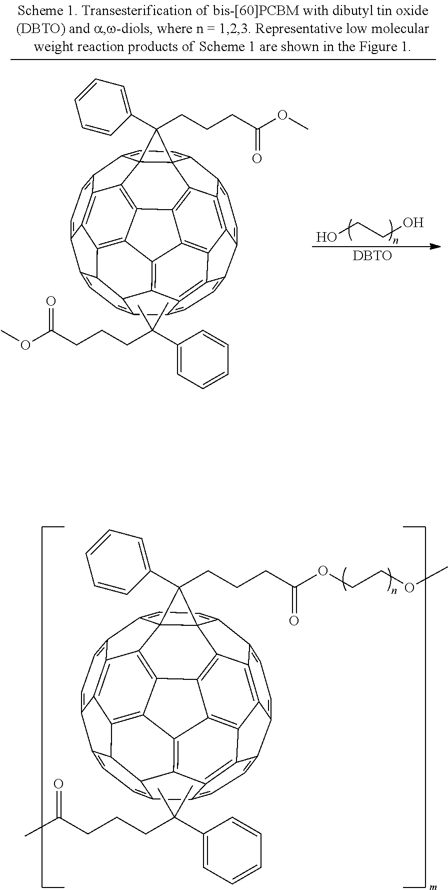

These macrocycle compounds in some instances of the present invention may be used in organic electronic applications, such as bulk heterojunction photodiodes, as additives to improve the solubility and/or precipitation behavior of a main component N-type. For example, a macrocycle polymer based on bis-[60]PCBM, since it is very soluble, may be used as an additive in for example about 0.1%, about 1%, about 5%, or about 10 mol % or more concentration in the fullerene derivative composition, in combination with for example C60, present in concentrations of about 50% or more, in order to allow more C60 to be dissolved in the solvent used for blending the N-type and P-type components, and/or to alter the precipitation behavior of the N-type/P-type mixture and thus alter morphology of the device film in a desirable manner. As the bis-[60]PCBM macrocycle polymer has a higher LUMO than the C60, it may be present in amounts where the hole trapping ability is not significant, but large enough to desirably alter morphology. Likewise, other macrocycle compounds, based on different fullerenes or different diols may be used, in combination with other main components, such as but not limited to [60]PCBM or [70]PCBM. Similarly, a C70 or other fullerene main component could be used with a bis-macrocycle polymer as additive.

Analogous to the above, the fullerene-containing macrocycle polymers can be formed with other multi-adducts, such as methanofullerene multi-adducts, multi-adduct Prato derivative; multi-adduct Diels-Alder fullerene derivatives; multi-adduct diazoline derivatives; multi-adduct Bingel derivatives; multi-adduct ketolactams; and multi-adduct azafulleroids as described in PCT/US07/72965 (which is hereby incorporated by reference in its entirety), wherein the derivative contains terminal ester groups, or other reactive groups whereby the derivative moieties may be reacted to form chemical bonds between the derivative moieties to form the macrocyle polymer compounds.

### Definitions

“Multi-adduct” refers to fullerene derivatives of two or more addend moieties, which addend moieties are the same or different than the mono-adduct moiety, and which are prepared by the successive reaction of the mono-adduct subjected to the same or different chemical reaction conditions which produced the mono-adduct. For example, multi-adducts can be formed by allowing the mono-adduct to continue reacting with the addition reactant, with or without the use of additional equivalents of addition reactant compared to what is normally used in mono-adduct preparation; or through isolation of the mono-adduct and subsequent reaction to form multi-adducts. “Multi-adducts” may or may not also be present in the form of a mixture of isomeric forms; wherein the relative positions of the addend moieties are different. “Multi-adducts” may also refer to compounds where the individual addend moieties are the same or different. The fullerene can be of any number of carbons, for example, C60, C70, C76, C78, C84, C90, or other fullerenes.

“Bis-adduct” refers to a multi-adduct as described above, wherein two addend moieties are bonded chemically to the fullerene core. The two moieties may be the same or different. Likewise, “tris-adduct” refers to three addends, the same or different, “tetra-adduct” refers to 4, penta to 5, hexa to 6, and so on.

“bis-[60]PCBM” refers to a molecule of the following general structure:

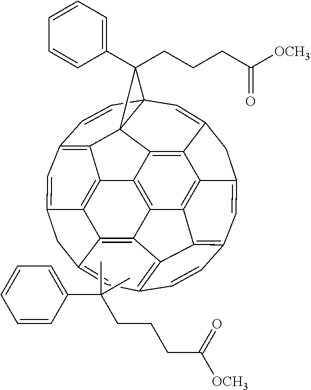

which is present in the form of one or more regio-isomers.

“tris-[60]PCBM refers to a molecule of the following general structure:

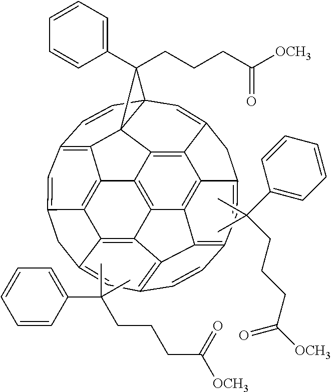

which is present in the form of one or more regio-isomers.

“tetra-[60]PCBM” refers to a molecule of the following general structure:

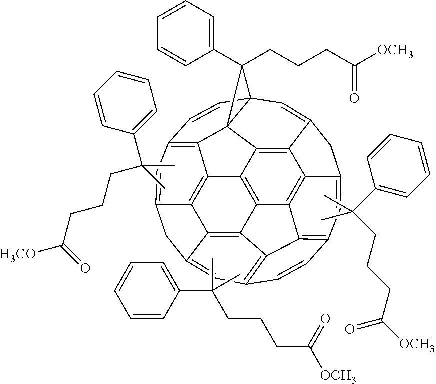

which is present in the form of one or more regio-isomers.

Similar to the above, “bis-[70]PCBM,” “tris-[70]PCBM,” and “tetra-[70]PCBM” are analogous to the structures above, wherein the C60 is replaced with a C70, and present in the form of regio-isomer mixtures. And similarly, penta-adduct, hexa-adduct, and adducts of higher number refer to molecules consisting of mixtures of regio-isomers of 5, 6, or higher number respectively.

“Main Component” refers to the compound of the present compositions which is present in the highest proportion relative to the other components in the composition.

A “methanofullerene” multi-adduct refers to the general structure:

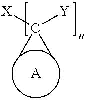

The —C(X)(Y)— group is bonded to the fullerene via a methano-bridge, as obtained through the well-known diazoalkane addition chemistry (W. Andreoni (ed.), The chemical Physics of Fullerenes 10 (and 5) Years Later, 257-265, Kluwer, 1996.) and X and Y are aryl, alkyl, or other chemical moieties which can be suitably bonded via the diazoalkane addition either by modification of the diazoalkane precursor or after the diazoalkane addition by modification of the fullerene derivative. In one embodiment, X is an un-substituted aryl, and Y is Butyric-Acid-Methyl-Ester. This molecule is commonly termed PCBM. Another example of a methanofullerene derivative is ThCBM, where X is thiophenyl, and Y is Butyric-Acid-Methyl-Ester. In the mono-adduct derivative, n is 1; in the bis-adduct derivative, n is 2, and so on. [60]methanofullerene refers to the compound based on C60, and [70]methanofullerene refers to the compound based on C70.

The definitions of multi-adduct Prato derivatives; multi-adduct Diels-Alder fullerene derivatives; multi-adduct diazoline derivatives; multi-adduct Bingel derivatives; multi-adduct ketolactams; and multi-adduct azafulleroids are as described in PCT/US07/72965 (which is hereby incorporated by reference in its entirety), wherein more than one addend moiety as described in PCT/US07/72965 (which is hereby incorporated by reference in its entirety) are bonded to the fullerene core, usually present in the form of a mixture of regio-isomers.

“Fullerene derivative addend moiety” refers here to the chemical entity chemically bonded to the fullerene, to form mono-adduct, bis-adduct, or a higher adduct. For example, the fullerene derivative addend moiety for bis-[60]PCBM is the PCBM moiety, which is present chemically bonded to the fullerene at two locations, and in the form of a mixture of regio-isomers where the locations of bonding of the PCBM moiety vary.

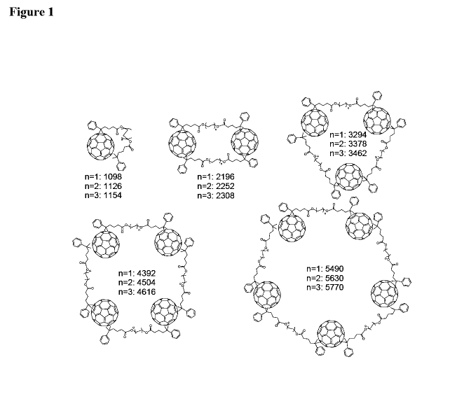

“Fullerene-containing macrocyle polymers” as used herein refers to compounds as shown in FIG. 1, and may contain from about 2 to about 100,000 fullerene units.

An example of a “multi-adduct consisting of 2 or more different addend moieties” is shown below:

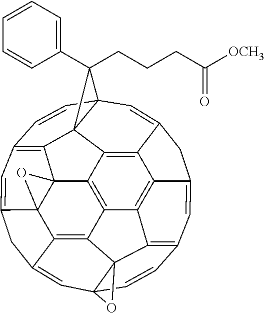

In the above example, two different addend moieties (a PCBM moiety and epoxide moieties) are present, to form a tris-adduct. This compound may be made by synthesizing PCBM as is known in the art, and then with or without isolation of the PCBM, exposing the PCBM to light (in UV and/or visible wavelengths) in the presence of air or oxygen. Similarly, multi-adducts consisting of different addend moieties may be prepared where instead of the epoxide, PCBM is further derivatized with one or more Prato, Diels-Alder, or other types of fullerene derivatives mentioned in this text or known in the art, with the synthetic techniques mentioned in this text or known in the art. The effect is to increase disruption of the double bond electronic structure of the fullerene to increase LUMO.

Alternatively, one or more Prato, Diels-Alder, or other types of fullerene derivatives mentioned in this text or known in the art, prepared with the synthetic techniques mentioned in this text or known in the art, may be formed first, and then subsequently derivatized with one or more Prato, Diels-Alder, or other types of fullerene derivatives mentioned in this text or known in the art, prepared with the synthetic techniques mentioned in this text or known in the art. To form a useful N-type composition, care must be taken as described elsewhere in this text, to eliminate compounds of different number of addends from the N-type composition, to less than about 20 mol %, or to about 0.1 mol % or less. And likewise, in some applications it may also be desired to eliminate unreacted fullerenes to levels of about 20% or less, or about 10% or less, or about 1% or less. Multi-adducts of 2 or more different addend moieties may also be formed with C70, C76, C78, C84, C90, or other fullerenes, and they may be present as a mixture of different regio-isomers.

A “fullerene dimer” refers to two fullerenes covalently bonded together, such as C₁₂₀, as described in Komatsu K.1; Fujiwara K.; Tanaka T.; Murata Y., “The fullerene dimer C₁₂₀ and related carbon allotropes,” Carbon, Volume 38, Number 11, 2000, pp. 1529-1534(6). Likewise “fullerene dimer” may refer to two fullerenes bonded together via a bridge, such as C₁₂₀O as described in Lebedkin S.; Ballenweg S.; Gross J.; Taylor R.; Kratschmer W., Tetrahedron Letters, Volume 36, Number 28, 10 Jul. 1995, pp. 4971-4974(4). Such fullerene dimers are also possible for C₇₀, C₇₆ C₇₈, C₈₄ and C₉₀, and may also occur between two fullerenes of different molecular weight, such as formed from C₆₀ and C₇₀.

“Endohedral fullerenes” refers to fullerenes (e.g., C₆₀, C₇₀, C₇₆ C₇₈, C₈₄ and C₉₀) which have a metallic or non-metallic element or compound contained within the fullerene cage, such as any described in the following references: Rep. Prog. Phys. 63, 843 (2000); Phys. Rev. B 64, 125402 (2001); J. Phys. Chem. B 105, 5839 (2001); Adv. Mater. Proc. Mater. Sci. Forum 282, 115 (1998); Chem. Phys. Lett. 317, 490 (2000); J. Chem. Phys. 117, 3484 (2002); J. Chem. Phys. 112, 2834 (2000); Chem. Commun. (2004) 1206; Phys. Rev. B. 72, 153411 (2005); Chem. Mater. 9 1773 (1997); M. S. Dresselhaus, G. Dresselhaus, P. C. Eklund, “Science of Fullerenes and Carbon Nanotubes, Academic Press, San Diego, 1996, pp. 132-133.; J. Am. Chem. Soc 123 181-182 (2001); Nucl. Instruments and Methods in Physic Research B 243 277-281 (2006); J. Radioanal. Nuclear Chem. 255(1) 155-158 (2003); Phys. Chem. A 104 3940-3942 (2000); J. Am. Chem. Soc. 129 5131-5138 (2007).

### Other Embodiments of the Invention

In addition to the embodiments described throughout the specification and claims, the Inventors have also contemplated the following embodiments:

A composition comprising one or more bis-adduct fullerene derivative, wherein the fullerene is C60, C70, C76, C78, C84, or C90;

one or more mono-adduct fullerene derivatives in the cumulative range of 0 mol % to about 20 mol %;

one or more tris-adduct fullerene derivatives in the cumulative range of 0 mol % to about 20 mol %; and

one or more multi-adduct fullerene derivatives with more than three addends in the cumulative range of 0 mol % to about 20 mol %.

In certain embodiments, the one or more mono-adduct fullerene derivatives are in the cumulative range of 0 mol % to about 2 mol %.

In certain embodiments, the one or more tris-adduct fullerene derivatives are in the cumulative range of 0 mol % to about 2 mol %.

In certain embodiments, the one or more multi-adduct fullerene derivatives with more than three addends are in the cumulative range of 0 mol % to about 2 mol %.

In certain embodiments, the one or more mono-adduct fullerene derivatives are in the cumulative range of 0 mol % to about 2 mol %; and the one or more tris-adduct fullerene derivatives are in the cumulative range of 0 mol % to about 2 mol %.

In certain embodiments, the one or more mono-adduct fullerene derivatives are in the cumulative range of 0 mol % to about 2 mol %; and the one or more multi-adduct fullerene derivatives with more than three addends are in the cumulative range of 0 mol % to about 2 mol %.

In certain embodiments, the one or more tris-adduct fullerene derivatives are in the cumulative range of 0 mol % to about 2 mol %; and the one or more multi-adduct fullerene derivatives with more than three addends are in the cumulative range of 0 mol % to about 2 mol %.

In certain embodiments, the one or more mono-adduct fullerene derivatives are in the cumulative range of 0 mol % to about 2 mol %; the one or more tris-adduct fullerene derivatives are in the cumulative range of 0 mol % to about 2 mol %; and the one or more multi-adduct fullerene derivatives with more than three addends are in the cumulative range of 0 mol % to about 2 mol %.

In certain embodiments, the one or more mono-adduct fullerene derivatives are in the cumulative range of 0 mol % to about 0.5 mol %.

In certain embodiments, the one or more tris-adduct fullerene derivatives are in the cumulative range of 0 mol % to about 0.5 mol %.

In certain embodiments, the one or more multi-adduct fullerene derivatives with more than three addends are in the cumulative range of 0 mol % to about 0.5 mol %.

In certain embodiments, the one or more mono-adduct fullerene derivatives are in the cumulative range of 0 mol % to about 0.5 mol %; and the one or more tris-adduct fullerene derivatives are in the cumulative range of 0 mol % to about 0.5 mol %.

In certain embodiments, the one or more mono-adduct fullerene derivatives are in the cumulative range of 0 mol % to about 0.5 mol %; and the one or more multi-adduct fullerene derivatives with more than three addends are in the cumulative range of 0 mol % to about 0.5 mol %.

In certain embodiments, the one or more tris-adduct fullerene derivatives are in the cumulative range of 0 mol % to about 0.5 mol %; and the one or more multi-adduct fullerene derivatives with more than three addends are in the cumulative range of 0 mol % to about 0.5 mol %.

In certain embodiments, wherein the one or more mono-adduct fullerene derivatives are in the cumulative range of 0 mol % to about 0.5 mol %; the one or more tris-adduct fullerene derivatives are in the cumulative range of 0 mol % to about 0.5 mol %; and the one or more multi-adduct fullerene derivatives with more than three addends are in the cumulative range of 0 mol % to about 0.5 mol %.

In certain embodiments, the one or more mono-adduct fullerene derivatives are in the cumulative range of 0 mol % to about 0.1 mol %.

In certain embodiments, the one or more tris-adduct fullerene derivatives are in the cumulative range of 0 mol % to about 0.1 mol %.

In certain embodiments, the one or more multi-adduct fullerene derivatives with more than three addends are in the cumulative range of 0 mol % to about 0.1 mol %.

In certain embodiments, the one or more mono-adduct fullerene derivatives are in the cumulative range of 0 mol % to about 0.1 mol %; and the one or more tris-adduct fullerene derivatives are in the cumulative range of 0 mol % to about 0.1 mol %.

In certain embodiments, the one or more mono-adduct fullerene derivatives are in the cumulative range of 0 mol % to about 0.1 mol %; and the one or more multi-adduct fullerene derivatives with more than three addends are in the cumulative range of 0 mol % to about 0.1 mol %.

In certain embodiments, the one or more tris-adduct fullerene derivatives are in the cumulative range of 0 mol % to about 0.1 mol %; and the one or more multi-adduct fullerene derivatives with more than three addends are in the cumulative range of 0 mol % to about 0.1 mol %.

In certain embodiments, the one or more mono-adduct fullerene derivatives are in the cumulative range of 0 mol % to about 0.1 mol %; the one or more tris-adduct fullerene derivatives are in the cumulative range of 0 mol % to about 0.1 mol % and; the one or more multi-adduct fullerene derivatives with more than three addends are in the cumulative range of 0 mol % to about 0.1 mol %.

A composition comprising one or more tris-adduct fullerene derivative, wherein the fullerene is C60, C70, C76, C78, C84, or C90;

one or more mono-adduct fullerene derivatives in the cumulative range of 0 mol % to about 20 mol %;

one or more bis-adduct fullerene derivatives in the cumulative range of 0 mol % to about 20 mol %; and

one or more multi-adduct fullerene derivatives with more than three addends in the cumulative range of 0 mol % to about 20 mol %.

In certain embodiments, the one or more mono-adduct fullerene derivatives are in the cumulative range of 0 mol % to about 2 mol %.

In certain embodiments, wherein the one or more bis-adduct fullerene derivatives are in the cumulative range of 0 mol % to about 2 mol %.

In certain embodiments, wherein the one or more multi-adduct fullerene derivatives with more than three addends are in the cumulative range of 0 mol % to about 2 mol %.

In certain embodiments, the one or more mono-adduct fullerene derivatives are in the cumulative range of 0 mol % to about 2 mol %; and the one or more bis-adduct fullerene derivatives are in the cumulative range of 0 mol % to about 2 mol %.

In certain embodiments, wherein the one or more mono-adduct fullerene derivatives are in the cumulative range of 0 mol % to about 2 mol %; and the one or more multi-adduct fullerene derivatives with more than three addends are in the cumulative range of 0 mol % to about 2 mol %.

In certain embodiments, the one or more bis-adduct fullerene derivatives are in the cumulative range of 0 mol % to about 2 mol %; and the one or more multi-adduct fullerene derivatives with more than three addends are in the cumulative range of 0 mol % to about 2 mol %.

In certain embodiments, wherein the one or more mono-adduct fullerene derivatives are in the cumulative range of 0 mol % to about 2 mol %; the one or more bis-adduct fullerene derivatives are in the cumulative range of 0 mol % to about 2 mol %; and the one or more multi-adduct fullerene derivatives with more than three addends are in the cumulative range of 0 mol % to about 2 mol %.

In certain embodiments, the one or more mono-adduct fullerene derivatives are in the cumulative range of 0 mol % to about 0.5 mol %.

In certain embodiments, wherein the one or more bis-adduct fullerene derivatives are in the cumulative range of 0 mol % to about 0.5 mol %.

In certain embodiments, wherein the one or more multi-adduct fullerene derivatives with more than three addends are in the cumulative range of 0 mol % to about 0.5 mol %.

In certain embodiments, wherein the one or more mono-adduct fullerene derivatives are in the cumulative range of 0 mol % to about 0.5 mol %; and the one or more bis-adduct fullerene derivatives are in the cumulative range of 0 mol % to about 0.5 mol %.

In certain embodiments, wherein the one or more mono-adduct fullerene derivatives are in the cumulative range of 0 mol % to about 0.5 mol %; and the one or more multi-adduct fullerene derivatives with more than three addends are in the cumulative range of 0 mol % to about 0.5 mol %.

In certain embodiments, wherein the one or more bis-adduct fullerene derivatives are in the cumulative range of 0 mol % to about 0.5 mol %; and the one or more multi-adduct fullerene derivatives with more than three addends are in the cumulative range of 0 mol % to about 0.5 mol %.

In certain embodiments, the one or more mono-adduct fullerene derivatives are in the cumulative range of 0 mol % to about 0.5 mol %; the one or more bis-adduct fullerene derivatives are in the cumulative range of 0 mol % to about 0.5 mol %; and the one or more multi-adduct fullerene derivatives with more than three addends are in the cumulative range of 0 mol % to about 0.5 mol %.

In certain embodiments, the one or more mono-adduct fullerene derivatives are in the cumulative range of 0 mol % to about 0.1 mol %.

In certain embodiments, the one or more bis-adduct fullerene derivatives are in the cumulative range of 0 mol % to about 0.1 mol %.

In certain embodiments, the one or more multi-adduct fullerene derivatives with more than three addends are in the cumulative range of 0 mol % to about 0.1 mol %.

In certain embodiments, the one or more mono-adduct fullerene derivatives are in the cumulative range of 0 mol % to about 0.1 mol %; and the one or more bis-adduct fullerene derivatives are in the cumulative range of 0 mol % to about 0.1 mol %.

In certain embodiments, the one or more mono-adduct fullerene derivatives are in the cumulative range of 0 mol % to about 0.1 mol %; and the one or more multi-adduct fullerene derivatives with more than three addends are in the cumulative range of 0 mol % to about 0.1 mol %.

In certain embodiments, the one or more bis-adduct fullerene derivatives are in the cumulative range of 0 mol % to about 0.1 mol %; and the one or more multi-adduct fullerene derivatives with more than three addends are in the cumulative range of 0 mol % to about 0.1 mol %.

In certain embodiments, the one or more mono-adduct fullerene derivatives are in the cumulative range of 0 mol % to about 0.1 mol %; the one or more bis-adduct fullerene derivatives are in the cumulative range of 0 mol % to about 0.1 mol %; and the one or more multi-adduct fullerene derivatives with more than three addends are in the cumulative range of 0 mol % to about 0.1 mol %.

A composition, comprising one or more tetra-adduct fullerene derivative, wherein the fullerene is C60, C70, C76, C78, C84, or C90;

one or more mono-adduct fullerene derivatives in the cumulative range of 0 mol % to about 20 mol %;

one or more bis-adduct fullerene derivatives in the cumulative range of 0 mol % to about 20 mol %;

one or more tris-adduct fullerene derivatives in the cumulative range of 0 mol % to about 20 mol %; and

one or more multi-adduct fullerene derivatives with more than four addends in the cumulative range of 0 mol % to about 20 mol %.

In certain embodiments, the one or more mono-adduct fullerene derivatives are in the cumulative range of 0 mol % to about 2 mol %.

In certain embodiments, the one or more bis-adduct fullerene derivatives are in the cumulative range of 0 mol % to about 2 mol %.

In certain embodiments, the one or more tris-adduct fullerene derivatives are in the cumulative range of 0 mol % to about 2 mol %.

In certain embodiments, the one or more multi-adduct fullerene derivatives with more than four addends are in the cumulative range of 0 mol % to about 2 mol %.

In certain embodiments, the one or more mono-adduct fullerene derivatives are in the cumulative range of 0 mol % to about 0.5 mol %.

In certain embodiments, the one or more bis-adduct fullerene derivatives are in the cumulative range of 0 mol % to about 0.5 mol %.

In certain embodiments, the one or more tris-adduct fullerene derivatives are in the cumulative range of 0 mol % to about 0.5 mol %.

In certain embodiments, the one or more multi-adduct fullerene derivatives with more than four addends are in the cumulative range of 0 mol % to about 0.5 mol %.

In certain embodiments, the one or more mono-adduct fullerene derivatives are in the cumulative range of 0 mol % to about 0.1 mol %.

In certain embodiments, the one or more bis-adduct fullerene derivatives are in the cumulative range of 0 mol % to about 0.1 mol %.

In certain embodiments, the one or more tris-adduct fullerene derivatives are in the cumulative range of 0 mol % to about 0.1 mol %.

In certain embodiments, the one or more multi-adduct fullerene derivatives with more than four addends are in the cumulative range of 0 mol % to about 0.1 mol %.

A composition comprising one or more penta-adduct fullerene derivative, wherein the fullerene is C60, C70, C76, C78, C84, or C90;

one or more mono-adduct fullerene derivatives in the cumulative range of 0 mol % to about 20 mol %;

one or more bis-adduct fullerene derivatives in the cumulative range of 0 mol % to about 20 mol %;

one or more tris-adduct fullerene derivatives in the cumulative range of 0 mol % to about 20 mol %;

one or more tetra-adduct fullerene derivatives in the cumulative range of 0 mol % to about 20 mol %; and

one or more multi-adduct fullerene derivatives with more than five addends in the cumulative range of 0 mol % to about 20 mol %.

In certain embodiments, the one or more mono-adduct fullerene derivatives are in the cumulative range of 0 mol % to about 2 mol %.

In certain embodiments, the one or more bis-adduct fullerene derivatives are in the cumulative range of 0 mol % to about 2 mol %.

In certain embodiments, the one or more tris-adduct fullerene derivatives are in the cumulative range of 0 mol % to about 2 mol %.

In certain embodiments, the one or more tetra-adduct fullerene derivatives are in the cumulative range of 0 mol % to about 2 mol %.

In certain embodiments, the one or more multi-adduct fullerene derivatives with more than five addends are in the cumulative range of 0 mol % to about 2 mol %.

In certain embodiments, the one or more mono-adduct fullerene derivatives are in the cumulative range of 0 mol % to about 0.5 mol %.

In certain embodiments, the one or more bis-adduct fullerene derivatives are in the cumulative range of 0 mol % to about 0.5 mol %.

In certain embodiments, wherein the one or more tris-adduct fullerene derivatives are in the cumulative range of 0 mol % to about 0.5 mol %.

In certain embodiments, the one or more tetra-adduct fullerene derivatives are in the cumulative range of 0 mol % to about 0.5 mol %.

In certain embodiments, the one or more multi-adduct fullerene derivatives with more than five addends are in the cumulative range of 0 mol % to about 0.5 mol %.

In certain embodiments, the one or more mono-adduct fullerene derivatives are in the cumulative range of 0 mol % to about 0.1 mol %.

In certain embodiments, the one or more bis-adduct fullerene derivatives are in the cumulative range of 0 mol % to about 0.1 mol %.

In certain embodiments, the one or more tris-adduct fullerene derivatives are in the cumulative range of 0 mol % to about 0.1 mol %.

In certain embodiments, the one or more tetra-adduct fullerene derivatives are in the cumulative range of 0 mol % to about 0.1 mol %.

In certain embodiments, the one or more multi-adduct fullerene derivatives with more than five addends are in the cumulative range of 0 mol % to about 0.1 mol %.

A composition comprising one or more hexa-adduct fullerene derivative, wherein the fullerene is C60, C70, C76, C78, C84, or C90;

one or more mono-adduct fullerene derivatives in the cumulative range of 0 mol % to about 20 mol %;

one or more bis-adduct fullerene derivatives in the cumulative range of 0 mol % to about 20 mol %;

one or more tris-adduct fullerene derivatives in the cumulative range of 0 mol % to about 20 mol %;

one or more tetra-adduct fullerene derivatives in the cumulative range of 0 mol % to about 20 mol %;

one or more penta-adduct fullerene derivatives in the cumulative range of 0 mol % to about 20 mol %; and

one or more multi-adduct fullerene derivatives with more than six addends in the cumulative range of 0 mol % to about 20 mol %.

In certain embodiments, the one or more mono-adduct fullerene derivatives are in the cumulative range of 0 mol % to about 2 mol %.

In certain embodiments, the one or more bis-adduct fullerene derivatives are in the cumulative range of 0 mol % to about 2 mol %.

In certain embodiments, the one or more tris-adduct fullerene derivatives are in the cumulative range of 0 mol % to about 2 mol %.

In certain embodiments, the one or more tetra-adduct fullerene derivatives are in the cumulative range of 0 mol % to about 2 mol %.

In certain embodiments,the one or more penta-adduct fullerene derivatives are in the cumulative range of 0 mol % to about 2 mol %.

In certain embodiments, the one or more multi-adduct fullerene derivatives with more than six addends are in the cumulative range of 0 mol % to about 2 mol %.

In certain embodiments, the one or more mono-adduct fullerene derivatives are in the cumulative range of 0 mol % to about 0.5 mol %.

In certain embodiments, the one or more bis-adduct fullerene derivatives are in the cumulative range of 0 mol % to about 0.5 mol %.

In certain embodiments, the one or more tris-adduct fullerene derivatives are in the cumulative range of 0 mol % to about 0.5 mol %.

In certain embodiments, the one or more tetra-adduct fullerene derivatives are in the cumulative range of 0 mol % to about 0.5 mol %.

In certain embodiments, the one or more penta-adduct fullerene derivatives are in the cumulative range of 0 mol % to about 0.5 mol %.

In certain embodiments, the one or more multi-adduct fullerene derivatives with more than six addends are in the cumulative range of 0 mol % to about 0.5 mol %.

In certain embodiments, the one or more mono-adduct fullerene derivatives are in the cumulative range of 0 mol % to about 0.1 mol %.

In certain embodiments, the one or more bis-adduct fullerene derivatives are in the cumulative range of 0 mol % to about 0.1 mol %.

In certain embodiments, wherein the one or more tris-adduct fullerene derivatives are in the cumulative range of 0 mol % to about 0.1 mol %.

In certain embodiments, the one or more tetra-adduct fullerene derivatives are in the cumulative range of 0 mol % to about 0.1 mol %.

In certain embodiments, the one or more penta-adduct fullerene derivatives are in the cumulative range of 0 mol % to about 0.1 mol %.

In certain embodiments, the one or more multi-adduct fullerene derivatives with more than six addends are in the cumulative range of 0 mol % to about 0.1 mol %.

In certain embodiments, the composition further comprising one or more unreacted fullerenes in the cumulative range of 0 mol % to about 20 mol %, 0 mol % to about 10 mol %, 0 mol % to about 2 mol %, or 0 mol % to about 0.5 mol %.

In certain embodiments, the one or more bis-adduct fullerene derivatives are bis-[60]PCBM or bis-[70]PCBM. In certain embodiments, the one or more tris-adduct fullerene derivatives are tris-[60]PCBM or tris-[70]PCBM. In certain embodiments, the one or more tetra-adduct fullerene derivatives are tetra-[60]PCBM or tetra-[70]PCBM. In certain embodiments, the one or more penta-adduct fullerene derivatives are penta-[60]PCBM or penta-[70]PCBM. In certain embodiments, the one or more hexa-adduct fullerene derivatives are hexa-[60]PCBM or hexa-[70]PCBM. In certain embodiments, the multi-adduct fullerene derivatives are multi-adduct-[60]PCBM or multi-adduct-[70]PCBM.

In certain embodiments, the bis-adduct fullerene derivatives are a combination of bis-[60]PCBM and bis-[70]PCBM. In certain embodiments, the tris-adduct fullerene derivatives are a combination of tris-[60]PCBM and tris-[70]PCBM. In certain embodiments, the tetra-adduct fullerene derivatives are a combination of tetra-[60]PCBM and tetra-[70]PCBM. In certain embodiments, the penta-adduct fullerene derivatives are a combination of penta-[60]PCBM and penta-[70]PCBM. In certain embodiments, the hexa-adduct fullerene derivatives are a combination of hexa-[60]PCBM and hexa-[70]PCBM. In certain embodiments, the multi-adduct fullerene derivatives are a combination of multi-adduct-[60]PCBM and multi-adduct-[70]PCBM.

In certain embodiments, the one or more bis-adduct fullerene derivatives are bis-methanofullerene. In certain embodiments, the one or more tris-adduct fullerene derivatives are tris-methanofullerene. In certain embodiments, the one or more tetra-adduct fullerene derivatives are tetra-methanofullerene. In certain embodiments, the one or more penta-adduct fullerene derivatives are penta-methanofullerene. In certain embodiments, the one or more hexa-adduct fullerene derivatives are hexa-methanofullerene. In certain embodiments, the one or more multi-adduct fullerene derivatives are methanofullerenes.

In certain embodiments, the bis-adduct fullerene derivatives are a combination of bis-[60]methanofullerene and bis-[70]methanofullerene. In certain embodiments, the tris-adduct fullerene derivatives are a combination of tris-[60]methanofullerene and tris-[70]methanofullerene. In certain embodiments, the tetra-adduct fullerene derivatives are a combination of tetra-[60]methanofullerene and tetra-[70]methanofullerene. In certain embodiments, the penta-adduct fullerene derivatives are a combination of penta-[60]methanofullerene and penta-[70]methanofullerene. In certain embodiments, the hexa-adduct fullerene derivatives are a combination of hexa-[60]methanofullerene and hexa-[70]methanofullerene. In certain embodiments, the multi-adduct fullerene derivatives are a combination of multi-adduct-[60]methanofullerene and multi-adduct-[70]methanofullerene.

In certain embodiments of the aforementioned compositions, the fullerene derivatives are selected from the group consisting of methanofullerene derivatives, Prato fullerene derivatives, Diels-Alder fullerene derivatives, diazoline fullerene derivatives, Bingel fullerene derivatives, ketolactam fullerene derivatives, and azafulleroid fullerene derivatives.

In certain embodiments of the aforementioned, the fullerene derivatives are selected from the group consisting of methanofullerene derivatives, Prato fullerene derivatives, Diels-Alder fullerene derivatives, diazoline fullerene derivatives, Bingel fullerene derivatives, ketolactam fullerene derivatives, and azafulleroid fullerene derivatives; and the fullerene derivatives are derivatives of C60.

In certain embodiments, the fullerene derivatives are selected from the group consisting of methanofullerene derivatives, Prato fullerene derivatives, Diels-Alder fullerene derivatives, diazoline fullerene derivatives, Bingel fullerene derivatives, ketolactam fullerene derivatives, azafulleroid fullerene derivatives, and fullerene derivatives; and wherein the fullerene derivatives are derivatives of C70.

In certain embodiments, the fullerene derivatives are selected from the group consisting of methanofullerene derivatives, Prato fullerene derivatives, Diels-Alder fullerene derivatives, diazoline fullerene derivatives, Bingel fullerene derivatives, ketolactam fullerene derivatives, and azafulleroid fullerene derivatives; the fullerene derivatives are derivatives of C60 and derivatives of C70; and the type and number of addends are identical.

A composition consisting essentially of a bis-adduct fullerene derivative, wherein the fullerene is C60, C70, C76, C78, C84, or C90;

a mono-adduct fullerene derivatives in the cumulative range of 0 mol % to about 20 mol %; and

a tris-adduct fullerene derivatives in the cumulative range of 0 mol % to about 20 mol %.

In certain embodiments, wherein the mono-adduct fullerene derivatives are in the cumulative range of 0 mol % to about 2 mol %.

In certain embodiments, the tris-adduct fullerene derivatives are in the cumulative range of 0 mol % to about 2 mol %.

In certain embodiments, the mono-adduct fullerene derivatives are in the cumulative range of 0 mol % to about 2 mol %; and the tris-adduct fullerene derivatives are in the cumulative range of 0 mol % to about 2 mol %.

In certain embodiments, the mono-adduct fullerene derivatives are in the cumulative range of 0 mol % to about 0.5 mol %.

In certain embodiments, the tris-adduct fullerene derivatives are in the cumulative range of 0 mol % to about 0.5 mol %.

In certain embodiments, the mono-adduct fullerene derivatives are in the cumulative range of 0 mol % to about 0.5 mol %; and the tris-adduct fullerene derivatives are in the range of 0 mol % to about 0.5 mol %.

In certain embodiments, the mono-adduct fullerene derivatives are in the cumulative range of 0 mol % to about 0.1 mol %.

In certain embodiments, the tris-adduct fullerene derivatives are in the cumulative range of 0 mol % to about 0.1 mol %.

In certain embodiments, the mono-adduct fullerene derivatives are in the cumulative range of 0 mol % to about 0.1 mol %; and the tris-adduct fullerene derivatives are in the cumulative range of 0 mol % to about 0.1 mol %.

In certain embodiments of the aforementioned composition, the fullerene is C60.

In certain embodiments of the aforementioned composition, the fullerene is C70.

In certain embodiments, the fullerene derivative is selected from the group consisting of a methanofullerene derivatives, Prato adduct fullerenes derivatives, Diels-Alder fullerene derivatives, diazoline fullerene derivatives, Bingel fullerene derivatives, ketolactam fullerene derivatives, and azafulleroid fullerene derivatives.

In certain embodiments, the adduct fullerene derivative is a methanofullerene derivative.

In certain embodiments, the methanofullerene derivative is selected from the group consisting of a PCBM fullerene derivative, a ThCBM derivative, a 3,4-OMe PCBM derivative, a PCB—CₙH₂ₙ₊₁ derivative and a methoxy PCBM derivative.

In certain embodiments, the bis-adduct fullerene derivatives are selected from the group consisting of bis-[60]PCBM fullerene derivative, bis-[70]PCBM fullerene derivative, bis-[60]ThCBM fullerene derivative, bis-[70]ThCBM fullerene derivative, 3,4-OMe-[60]PCBM bis adduct, 3,4-OMe-[70]PCBM bis adduct, bis[60]PCB—C4, bis[70]PCB—C4, bis[60]PCB—C8, bis[70]PCB—C8, mono-Methoxy-mono-[60]PCBM and mono-Methoxy-mono-[70]PCBM.

A composition consisting essentially of:

a tris-adduct fullerene derivative;

wherein the fullerene is C60, C70, C76, C78, C84, or C90;

a bis-adduct fullerene derivatives in the cumulative range of 0 mol % to about 20 mol %; and

a tetra-adduct fullerene derivatives in the cumulative range of 0 mol % to about 20 mol %.

In certain embodiments, the bis-adduct fullerene derivatives are in the cumulative range of 0 mol % to about 2 mol %.

In certain embodiments, the tetra-adduct fullerene derivatives are in the cumulative range of 0 mol % to about 2 mol %.

In certain embodiments, the bis-adduct fullerene derivatives are in the cumulative range of 0 mol % to about 2 mol %; and the tetra-adduct fullerene derivatives are in the cumulative range of 0 mol % to about 2 mol %.

In certain embodiments, the bis-adduct fullerene derivatives are in the cumulative range of 0 mol % to about 0.5 mol %.

In certain embodiments, the tetra-adduct fullerene derivatives are in the cumulative range of 0 mol % to about 0.5 mol %.

In certain embodiments, the bis-adduct fullerene derivatives are in the cumulative range of 0 mol % to about 0.5 mol %; and the tetra-adduct fullerene derivatives are in the cumulative range of 0 mol % to about 0.5 mol %.

In certain embodiments, the bis-adduct fullerene derivatives are in the cumulative range of 0 mol % to about 0.1 mol %.

In certain embodiments, the tetra-adduct fullerene derivatives are in the cumulative range of 0 mol % to about 0.1 mol %.

In certain embodiments, the bis-adduct fullerene derivatives are in the cumulative range of 0 mol % to about 0.1 mol %; and the tetra-adduct fullerene derivatives are in the cumulative range of 0 mol % to about 0.1 mol %.

In certain embodiments of the aforementioned composition, the fullerene is C60.

In certain embodiments of the aforementioned composition, the fullerene is C70.

In certain embodiments, the fullerene derivative is selected from the group consisting of a methanofullerene derivative, Prato adduct fullerene derivative, Diels-Alder fullerene derivative, diazoline fullerene derivative, Bingel fullerene derivative, ketolactam fullerene derivative, azafulleroid fullerene derivative, and other tris-adduct fullerene derivative.

In certain embodiments, the fullerene derivative is a methanofullerene derivative.

In certain embodiments, wherein the methanofullerene derivative is selected from the group consisting of a PCBM fullerene derivative, a ThCBM derivative, a 3,4-OMe PCBM derivative, a PCB—CₙH₂ₙ₊₁ derivative and a methoxy PCBM derivative.

In certain embodiments, the tris-adduct fullerene derivatives are selected from the group consisting of tris-[60]PCBM fullerene derivative, tris-[70]PCBM fullerene derivative, tris-[60]ThCBM fullerene derivative, tris-[70]ThCBM fullerene derivative, 3,4-OMe-[60]PCBM tris adduct, 3,4-OMe-[70]PCBM tris adduct, tris[60]PCB—C4, tris[70]PCB—C4, bis[60]PCB—C8, bis[70]PCB—C8, mono-Methoxy-bis-[60]PCBM and mono-Methoxy-bis-[70]PCBM.

A composition comprising:

a macrocyclic polymer comprising repeating units;

wherein the repeating units are independently one or more bis-adduct fullerene derivatives; and the one or more bis-adduct fullerene derivatives are covalently linked via a plurality of tethers, where each of said tethers comprise at least one heteroatom.

In certain embodiments, the one or more bis-adduct fullerene derivatives are selected from the group consisting of a bis methanofullerene derivative, bis-Prato adduct fullerene derivative, bis-Diels-Alder fullerene derivative, bis-diazoline fullerene derivative, bis-Bingel fullerene derivative, bis-ketolactam fullerene derivative, bis-azafulleroid fullerene derivative, and other bis-adduct fullerene derivatives.

In certain embodiments, the one or more bis-adduct fullerene derivatives are a derivative of C60, C70, C76, C78, C84, or C90.

In certain embodiments, the one or more bis-adduct fullerene derivatives are a combination of a derivative of C60, C70, C76, C78, C84, or C90; and the type of addends are identical.

In certain embodiments, the one or more bis adduct fullerene derivative is bis-[60]PCBM fullerene derivative or bis-[70]PCBM fullerene derivative.

In certain embodiments, the invention relates to the use of any one of the aforementioned compositions as an additive to improve morphology in bulk heterojunction photodiodes.

In certain embodiments, the invention relates to the use of the compositions of any one of the aforementioned compositions as a semiconductor in an organic electronics application.

In certain embodiments, the invention relates to a semiconductor comprising any one of the aforementioned compositions.

In certain embodiments, the invention relates to a photodiode comprising any one of the aforementioned compositions.

In certain embodiments, the invention relates to a photovoltaic device, comprising any one of the aforementioned compositions.

In certain embodiments, the invention relates to a solar cell comprising any one of the aforementioned compositions.

In certain embodiments, the invention relates to a photodetector comprising any one of the aforementioned compositions.

In certain embodiments, the invention relates to a transistor comprising any one of the aforementioned compositions.

A composition, comprising

one or more fullerene derivatives,

wherein each fullerene derivative bears exactly n addends;

n is independently greater than or equal to 2;

the derivatized fullerenes are independently C60, C70, C76, C78, C84 or C90;

the fullerene derivative present in the largest mol % has a first initial reduction potential;

the combined amount of fullerene derivatives with a second initial reduction potential between about 50 meV and 150 meV greater than the first initial reduction potential is 0 mol % to about 5 mol %;

the combined amount of fullerene derivatives with a third initial reduction potential between 150 meV and about 250 meV greater than the first initial reduction potential is 0 mol % to about 2 mol %; and

the combined amount of fullerene derivatives with a fourth initial reduction potential at least about 100 meV less than the first initial reduction potential is 0 mol % to about 10 mol %.

In certain embodiments, the derivatized fullerene is C60 or C70. In certain embodiments, the derivatized fullerene is C60. In certain embodiments, the derivatized fullerene is C70.

In certain embodiments, the combined amount of fullerene derivatives with a second initial reduction potential between about 50 meV and 150 meV greater than the first initial reduction potential is 0 mol % to about 2 mol %.

In certain embodiments, the combined amount of fullerene derivatives with a second initial reduction potential between about 50 meV and 150 meV greater than the first initial reduction potential is 0 mol % to about 0.5 mol %.

In certain embodiments, the combined amount of fullerene derivatives with a second initial reduction potential between about 50 meV and 150 meV greater than the first initial reduction potential is 0 mol % to about 0.1 mol %.

In certain embodiments, the combined amount of fullerene derivatives with a third initial reduction potential between 150 meV and about 250 meV greater than the first initial reduction potential is 0 mol % to about 0.5 mol %.

In certain embodiments, the combined amount of fullerene derivatives with a third initial reduction potential between 150 meV and about 250 meV greater than the first initial reduction potential is 0 mol % to about 0.1 mol %.

In certain embodiments, the combined amount of fullerene derivatives with a fourth initial reduction potential at least about 100 meV less than the first initial reduction potential is 0 mol % to about 5 mol %.

In certain embodiments, the combined amount of fullerene derivatives with a fourth initial reduction potential at least about 100 meV less than the first initial reduction potential is 0 mol % to about 2 mol %.

In certain embodiments, the combined amount of fullerene derivatives with a fourth initial reduction potential at least about 100 meV less than the first initial reduction potential is 0 mol % to about 0.5 mol %.

In certain embodiments, the combined amount of fullerene derivatives with a fourth initial reduction potential at least about 100 meV less than the first initial reduction potential is 0 mol % to about 0.1 mol %.

A composition, comprising:

one or more fullerene derivatives, wherein the fullerene derivative present in the largest mol % bears exactly n addends;

n is independently greater than or equal to 2;

the derivatized fullerenes are independently C60, C70, C76, C78, C84 or C90;

the combined amount of fullerene derivatives with less than or equal to n−2 addends is 0 mol % to about 2 mol %;

the combined amount of fullerene derivatives with n−1 addends is 0 mol % to about 5 mol %; and

the combined amount of fullerene derivatives with greater than or equal to n+1 addends is 0 mol % to about 10 mol %.

In certain embodiments, the derivatized fullerene is C60 or C70. In certain embodiments, the derivatized fullerene is C60. In certain embodiments, the derivatized fullerene is C70.

In certain embodiments, the combined amount of fullerene derivatives with less than or equal to n−2 addends is 0 mol % to about 0.5 mol %. In certain embodiments, the combined amount of fullerene derivatives with less than or equal to n−2 addends is 0 mol % to about 0.1 mol %. In certain embodiments, the combined amount of fullerene derivatives with n−1 addends is 0 mol % to about 2 mol %. In certain embodiments, the combined amount of fullerene derivatives with n−1 addends is 0 mol % to about 0.5 mol %. In certain embodiments, the combined amount of fullerene derivatives with n−1 addends is 0 mol % to about 0.1 mol %.

In certain embodiments, the combined amount of fullerene derivatives with greater than or equal to n+1 addends is 0 mol % to about 5 mol %. In certain embodiments, the combined amount of fullerene derivatives with greater than or equal to n+1 addends is 0 mol % to about 2 mol %. In certain embodiments, the combined amount of fullerene derivatives with greater than or equal to n+1 addends is 0 mol % to about 0.5 mol %. In certain embodiments, the combined amount of fullerene derivatives with greater than or equal to n+1 addends is 0 mol % to about 0.1 mol %.

In certain embodiments, the invention relates to any one of the aforementioned compositions, wherein the fullerene derivative present in the largest mol % consists of either a single regio-isomer, less than or equal to three regio-isomers, less than or equal to six regio-isomers, less than or equal to nine regio-isomers, or less than or equal to twelve regio-isomers.

In certain embodiments, the invention relates to any one of the aforementioned compositions, wherein the fullerene is a fullerene dimer.

In certain embodiments, the invention relates to any one of the aforementioned compositions, wherein the fullerene is a endohedral fullerene.

In certain embodiments, the invention relates to the use of any one of the aforementioned compositions as an N-type semiconductor in an organic electronics application.

In certain embodiments, the invention relates to a photodiode comprising any one of the aforementioned compositions.

In certain embodiments, the invention relates to a photovoltaic device, comprising any one of the aforementioned compositions.

In certain embodiments, the invention relates to a method of preparing a fullerene-containing macrocyclic polymer by reacting the one or more bis-adduct fullerene derivative, with or without a catalyst, to give a reaction product comprising a macrocyclic polymer.

In certain embodiments, the one or more bis-adduct fullerene derivatives are selected from the group consisting of a bis methanofullerene derivative, bis-Prato adduct fullerene derivative, bis-Diels-Alder fullerene derivative, bis-diazoline fullerene derivative, bis-Bingel fullerene derivative, bis-ketolactam fullerene derivative, and bis-azafulleroid fullerene derivative.

In certain embodiments, the one or more bis-adduct fullerene derivatives are a derivative of C60, C70, C76, C78, C84, or C90.

In certain embodiments, the one or more bis-adduct fullerene derivatives are a combination of a derivative of C60, C70, C76, C78, C84, or C90; and type and number of addends are identical.

In certain embodiments, the one or more bis adduct fullerene derivative is bis-[60]PCBM fullerene derivative or bis-[70]PCBM fullerene derivative.

In certain embodiments, the macrocyclic polymer comprises from about 2 to about 100,000 fullerene derivative units.

In certain embodiments, the invention relates to a composition, comprising a macrocyclic polymer wherein the repeating units are bis-adduct fullerene derivatives, with or without diols of any number of carbons chemically bonded to the multi-adducts to accomplish the linking of the multi-adducts.

In certain embodiments, the invention relates to a method of producing a fullerene-containing macrocyclic polymer, wherein one or more bis-adduct fullerene derivatives, wherein the fullerene derivative moiety contains chemically reactive moieties, are reacted together at the chemically reactive site on the fullerene derivative, with or without a catalyst, to form a polymer.

In certain embodiments, the invention relates to a macrocyclic polymer composition or method of producing a fullerene-containing macrocyclic polymer above, wherein the bis-adduct fullerene derivatives are bis-methanofullerenes, bis-[60]PCBM, bis-[70]PCBM, bis-Prato adducts; bis-Diels-Alder fullerene derivatives; bis-diazoline derivatives; bis-Bingel derivatives; bis-ketolactams; or bis-azafulleroids; or any other bis-fullerene derivative known in the art, wherein, the bis-adduct fullerene derivatives comprise C60, C70, C76, C78, C84, C90, or a combination of C60, C70, C76, C78, C84, C90 bis-adducts, wherein the type and number of addends are identical.

In certain embodiments, the invention relates to a macrocycle polymer composition or method of producing a macrocyclic polymer, wherein the macrocycle polymer comprises from 2 to 100,000 fullerene derivative units.

In certain embodiments, the invention relates to the use of the macrocycle compounds described above as an additive to improve morphology in bulk heterojunction photodiodes.

In certain embodiments, the invention relates to the use of the macrocycle compounds described above as semiconductors in organic electronics applications.

In certain embodiments, the invention relates to a photodiode comprising any one of the above macrocycle compounds.

In certain embodiments, the invention relates to a solar cell comprising any one of the above macrocycle compounds.

In certain embodiments, the invention relates to a photodetector comprising any one of the above macrocycle compounds.

In certain embodiments, the invention relates to a transistor, comprising any one of the above macrocycle compounds.

In certain embodiments, the invention relates to a photovoltaic device, comprising any one of the above macrocycle compounds.

### Exemplification

The invention now being generally described, will be more readily understood by reference to the following examples, which are included merely for purposes of illustration of certain aspects and embodiments of the present invention, and are not intended to limit the scope of invention.

### EXAMPLE 1

### Synthesis of a Multi-Adduct, Measurement of Electron Mobility, and Use as an N-Type Semiconductor

A [60]fullerene bisadduct (bisPCBM) is presented with a 100 mV lower electron affinity as compared to the standard [6,6] -phenyl-C₆₁-butyric acid methyl ester (PCBM). By this raise of the lowest unoccupied molecular orbital (LUMO) level of the acceptor we increase the open circuit voltage of polymer:fullerene bulk heterojunction solar cells based on poly(3-hexylthiophene) (P3HT) by 0.15 V. As a result the energy loss in the electron transfer from donor to acceptor material is reduced. Maintaining high currents and fill factor a certified power conversion efficiency of 4.5% is reported for a P3HT:bisPCBM solar cell.

Looking at photovoltaics, polymer:fullerene bulk heterojunction (BHJ) solar cells are considered to be a promising candidate for a large area, flexible, and more importantly, low cost renewable energy source.' Despite considerable progress made in this area, the relatively low power conversion efficiencies, together with stability issues, are a drawback for commercialization of these devices. A significant part of the effort made in this field has been optimizing the fabrication of solar cells based on poly(3-hexylthiophene) (P3HT) as donor and [6,6]-phenyl-C₆₁-butyric acid methyl ester (PCBM) as acceptor.²⁻⁴ Especially the improvements made by thermal and solvent annealing have led to a situation where devices are made with external quantum efficiencies peaking around 80% and internal quantum efficiencies surpassing 90%, leading to power conversion efficiencies of about 4%. From the observed quantum efficiencies it is clear there is not much room for improvement for this combination of donor and acceptor.

When analyzing the electronic levels of the P3HT:PCBM system a significant loss mechanism can be identified; Due to the high exciton binding energy in conjugated polymers excitons are created rather than free carriers upon light absorption. By blending in an electron acceptor, it becomes energetically favorable for the electron to jump over to the acceptor, thus breaking up the exciton. For electron transfer from donor to acceptor to occur, the lowest unoccupied molecular orbital (LUMO) of the unexcited donor needs to be 0.3 to 0.5 eV higher than the LUMO of the acceptor.^{5,6} In the case of P3HT however, this energy difference is much higher, namely 1.1 eV. This results in a less then optimal open circuit voltage V_{oc}, since the open-circuit voltage is ultimately limited by the difference between the HOMO of the excited donor and the LUMO of the acceptor.^{6,7} There are two ways to reduce this energy offset, at the donor or at the acceptor side. Upon lowering the LUMO of the unexcited donor, and thus lowering the polymer band gap, the absorption is shifted towards lower energy whilst maintaining a constant open circuit voltage. In this approach it is the photocurrent that is mainly approved due to an enhanced overlap of the donor absorption with the solar spectrum.⁸ Making use of a recently developed device model for polymer:fullerene BHJ solar cells⁹ it has been calculated that a lowering of the LUMO of the unexcited donor leads ultimately to efficiencies in the order of 6.5%.¹⁰ This efficiency can be further enhanced by applying these low band gap polymers in tandem configurations.^{11,12} Raising the LUMO of the acceptor, on the other hand, will directly result in a higher open circuit voltage unaffecting the absorption of the cell. It has been shown that the second approach is theoretically more beneficial for a single layer solar cell, resulting in an estimated efficiency of 8.4% when the LUMO offset is reduced to 0.5 eV.¹⁰ Until now acceptors with a higher LUMO compared to PCBM, like for instance polymer acceptors¹³ or alternative fullerenes,¹⁴ suffer from negative side effects like insufficient charge transport, inefficient charge dissociation or morphology problems.

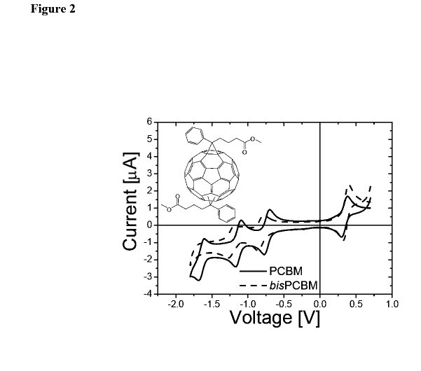

Here we introduce bisPCBM, which is the bisadduct analogue of [60]PCBM, as a new fullerene based N-type semiconductor material. BisPCBM is normally obtained as a side product in the preparation of PCBM (Hummelen, et al. Journal of Organic Chemistry, 60, pp. 532-538, 1995). The material consists of a large number of regio-isomers. The general structure of these isomers (with the second addend at various positions on the fullerene cage) is depicted in FIG. 2. The pure mixture of bisadducts (free of monoadduct and higher adducts) was used as such (about 0.1 mol % each of mono-adduct PCBM and tris-adduct PCBM or less were present). BisPCBM has a substantially higher LUMO than PCBM, as can be seen by cyclo-voltametric (CV) comparison of bisPCBM and PCBM (FIG. 2). An increase of the LUMO level of about 100 meV was found, raising the LUMO to 3.7 eV below the vacuum level.

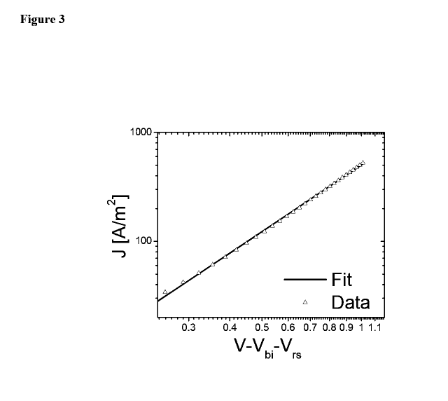

As a next step, layers of pristine bisPCBM were investigated to see whether the additional functionalization of the fullerene has any negative side effects on the charge transport properties. The electron transport through the fullerene was measured by sandwiching a layer of bisPCBM between a layer of Indium Tin Oxide (ITO) covered with about 70 nm of poly(3,4-ethylenedioxythiophene):poly(styrenesulfonate) (PEDOT:PSS) and a samarium(5 nm)/aluminium(100 nm) top electrode. Since the work function of PEDOT:PSS (5.2 eV) is significantly lower then the HOMO of bisPCBM (6.1 eV), hole injection into the fullerene can be neglected and only electrons flow at forward bias. FIG. 3 shows the J-V characteristics of a bisPCBM electron only device with a thickness of 182 nm, with the applied voltage corrected for the built-in voltage and series resistance of the contact. The transport through these single carrier devices is space-charge limited, resulting in a low-field electron mobility of 7×10⁻⁸ m²/Vs. The measured electron mobility for bisPCBM is only slightly lower than values reported for normal PCBM (2×10⁻⁷ m²/Vs),¹⁶ measured under the same conditions.

Next bisPCBM was used as an acceptor in a polymer:fullerene solar cells using the solvent annealing technique.² P3HT and bisPCBM were dissolved in 1,2-dichlorobenzene (ODCB) in a 1:1.2 weight ratio by stirring the mixture for 2 days. The blend was spin cast on top of ITO covered with PEDOT:PSS and left to dry in a closed petri dish for 48 hours. After the solvent annealing a short (5 minute) thermal annealing step was done at 110° C. To finish the devices a samarium(5 nm)/aluminum(100 nm) top contact was evaporated. The optimal active layer thickness for P3HT:bisPCBM was found to be about 250-300 nm. After fabrication the samples were evaluated and the best cells were shipped inside a nitrogen filled container to the Energy research Centre of the Netherlands (ECN), to accurately determine the device performance. As a reference, P3HT cells with normal PCBM in a 1:1 weight ratio were made with the same fabrication procedure. The optimal thickness of these cells was somewhat higher than for bisPCBM, around 350 nm

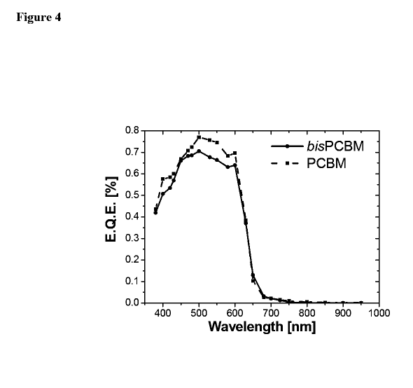

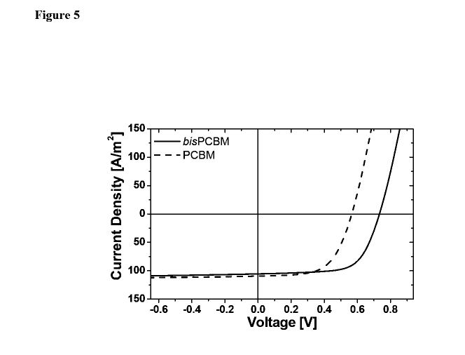

FIG. 4 shows the external quantum efficiency determined at ECN for P3HT:bisPCBM and P3HT:PCBM solar cells. Even though similar in shape normal PCBM devices result in slightly higher external quantum efficiencies, probably due to a thicker active layer. From the EQE measurements the short circuit current under AM 1.5 conditions was estimated to be 96 A/m² for P3HT:bisPCBM versus 104 A/m² for P3HT:PCBM. FIG. 5 shows the J-V characteristics of the cells measured under a 1000 W/m² illumination using a halogen lamp. The open circuit voltage of the P3HT:bisPCBM cell amounted to 0.73 V, which is 0.15 V higher than the cell with P3HT:PCBM. As predicted by the EQE measurements the short circuit current is only slightly lower for P3HT:bisPCBM. Due to the enhanced V_{oc}, bisPCBM is clearly the superior acceptor in combination with P3HT. In order to accurately quote efficiencies, calibrated measurements are needed. Our best cell was measured under a 1000 W/m², simulated AM1.5 illumination from a WXS-300S-50 solar simulator (WACOM Electric Co.). The mismatch factor of 0.992 was calculated using a recent spectrum of the simulator lamp, the spectral responses of, respectively, the used filtered Si reference cell calibrated at Fraunhofer ISE, Freiburg and the polymer:fullerene cell. These certified measurements resulted in an open circuit voltage of 0.724 V, fill factor of 68% and a short circuit current of 91.4 A/m². The resulting power conversion efficiency amounts to 4.5% for the P3HT:bisPCBM solar cell with an active area of 0.16 cm². Devices with larger active areas of 1 cm² showed a small decrease in fill factor to 62%, resulting in efficiencies of 4.1%. The discrepancy between the calculated short circuit current from the EQE measurements and the AM 1.5 current is probably due to the absence of a bias illumination during the EQE measurement. The efficiency of 4.5% is about a factor 1.2 larger as compared to the certified efficiencies of our best P3HT:PCBM cells of 3.8%. This improvement is entirely due to the increase of V_{oc}. A similar improvement is also expected for other polymer:fullerene systems, as for example low band gap cells for which 5% efficiency has been claimed recently.¹⁷

### REFERENCES CITED

¹ C. J. Brabec, N. S. Sariciftci and J. C. Hummelen, Adv. Fuct. Mater. 11, 15 (2001).
² G. Li, V. Shrotriya, J. Huang, Y. Yao, T. Moriarty, K. Emery, Y. Yang, Nat. Mater. 4, 864 (2005).
³ F. Padinger, R. S. Rittberger, and N. S. Sariciftci, Adv. Funct. Mater. 13, 85 (2003)
⁴ W. Ma, C. Yang, X. Gong, K. Lee, and A. J. Heeger, Adv. Funct. Mater.15, 1617 (2005).
⁵ J. J. M. Halls, J. Cornill, D. A. dos Santos, R. Silbey, D.-H. Hwang, A. B. Holmes, J. L. Brébas, and R. H. Friend, Phys. Rev. B 60, 5721 (1999).
⁶ C. J. Brabec, C. Winder, N. S. Sariciftci, J. C. Hummelen, A. Dhanabalan, P. A. van Hal, and R. A. J. Janssen, Adv. Funct. Mater. 12, 709 (2002)
⁷ L. J. A. Koster, V. D. Mihailetchi, R. Ramaker, and P. W. M. Blom, Appl. Phys. Lett. 86, 123509 (2005)
⁸ D. Mühlbacher, M. Scharber, M. Morana, Z. Zhu, D. Waller, R. Gaudiana, C. Brabec, Adv. Mater. 18, 2884 (2006)
⁹ L. J. A. Koster, E. C. P. Smits, V. D. Mihailetchi, P. W. M. Blom, Phys. Rev B 72, 085205 (2005).
¹⁰ L. J. A. Koster, V. D. Mihailetchi, P. W. M. Blom, Appl. Phys. Lett. 88, 093511 (2006)
¹¹ A. Hadipour, B. de Boer, J. Wildeman, F. B. Kooistra, J. C. Hummelen, M. G. R. Turbiez, M. M. Wienk, R. A. J. Janssen, P. W. M. Blom, Adv. Funct. Mater. 16, 1897 (2006)
¹² J. Y. Kim, K. Lee, N. E. Coates, D. Moses, T. Nguyen, M. Dante, A. J. Heeger, Science 317, 222 (2007)
¹³ C. R. McNeill, A. Abrusci, J. Zaumseil, R. Wilson, M. J. McKiernan, J. H. Burroughes, J. J. M. Halls, N. C. Greenham, R. H. Friend, Appl. Phys. Lett., 90, 193506 (2007)
¹⁴ F. B. Kooistra, J. Knol, F. Kastenberg, L. M. Popescu, W. J. H. Verhees, J. M. Kroon, and J. C. Hummelen Org. Lett. 9 551 (2007).
¹⁵ F. B. Kooistra, F. Brouwer and, J. C. Hummelen, to be published.
¹⁶ V. D. Mihailetchi, J. K. J. van Duren, P. W. M. Blom, J. C. Hummelen, R. A. J. Janssen, J. M. Kroon, M. T. Rispens, W. J. H. Verhees, M. M. Wienk, Adv. Funct. Mater. 13, 43 (2003)
¹⁷ J. Peet, J. Y. Kim, N. E. Coates, W. L. Ma, D. Moses, A. J. Heeger and G. C. Bazan, Nature Mat. 9, 497, (2007).

### EXAMPLE 2

### Synthesis and Characterization of Fullerene Macrocycle Compounds Using bis-Adduct Fullerene Derivatives as Pre-Cursors

Three dimensional structures containing buckminsterfullerene, C₆₀, have been studied widely ever since the discovery of C₆₀ by Kroto, Smalley, and Curl.¹ These structures are usually based on the complexing ability of fullerenes with conjugated systems which have either ball, bowl or belt shapes.² Macrocycles with pendant fullerenes were presented by Diederich et al.³ Now, for the first time, fullerene containing macrocycles, forming unique pearl-necklace structures, have been prepared. MALDI-TOF spectra unequivocally show cycles containing up to 8 fullerenes and more.

The synthesis of macrocycles has attracted much attention recently and numerous examples are known: synthesis of natural products containing cyclic structures,⁴ amino acid derived macrocycles,⁵ cyclo-oligomerization,⁶ pyrrole and porphyrine ring structures,⁷ and conjugated macrocycles.⁸ In polymer science, the formation of ring structures during polycondensation reactions has been studied extensively.⁹ Most polymeric ring systems are formed during polyesterification reactions. One of the most widely used catalysts in these types of reactions are alkyltinoxide compounds.¹⁰ The origin of the catalytic efficiency of alkyltinoxide was recently reviewed by Michel.¹¹ The catalytic species is a dimeric alkoxy distannoxane compound (1) which is formed in situ when the dialkyltinoxide reacts with the polymer ester functionalities (see scheme 2). First, the alkoxydistannoxane is formed, which coordinates to the ester. Subsequent alcoholysis yields the transesterified product.

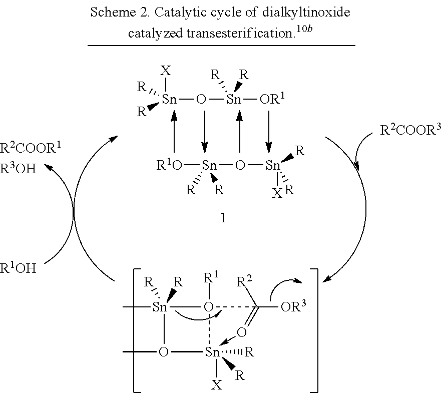

Baumhof et al. showed that this reaction is also applicable in small molecule transesterification reactions, using dibutyltinoxide (DBTO) as the catalyst.¹² We have previously applied this methodology in our labs to perform transesterification reactions on phenyl C₆₁ butyric methylester (PCBM).¹³ In an effort to synthesize fullerene containing polymers, pure bis-adducts of PCBM (2) were subjected to transesterification reactions with different α,ω-diols, using dibutyltinoxide as the catalyst (see scheme 1). Formation of large ring structures was found, however. Apparently, the low concentration conditions under which the reactions were performed (due to the low solubility of fullerenes), facilitated the formation of ring structures. Since fullerenes are known to form aggregates in solution, we suggest that the formation of fullerene aggregates in solution may favor the formation of ring structures even more. Interestingly, even the largest structures that were formed did not precipitate from the solvent (o-dichlorobenzene). The solubility of the macrocycles opens up the possibility of applying these structures in, for example, organic electronics.

Next, we tried to selectively synthesize a cycle consisting of only two fullerenes (4), in order to be able to fully characterize the macrocycle (see scheme 3). First, bis-PCBM (2) was transesterified by allowing it to react with a large excess of 1,6-bishexanol (40 eq.), using DBTO as the catalyst. The bis-esterified product (3) was obtained successfully. This product was then allowed to react with bis-PCBM (2) in a stoichiometric fashion, once again applying DBTO as the catalyst. The reaction, however, yielded a mixture of rings of various sizes.

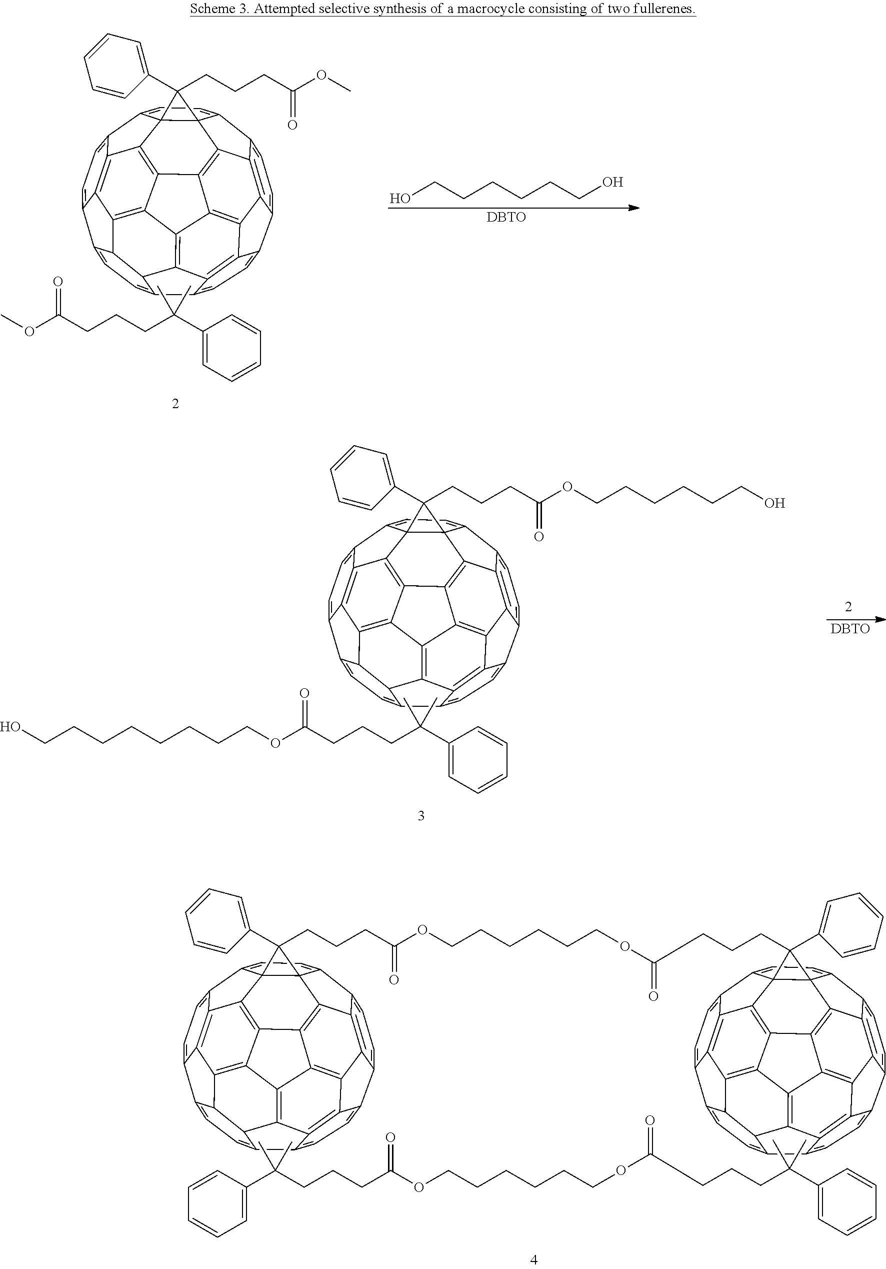

All products were analyzed by MALDI-TOF spectroscopy. Besides masses of large cyclic structures, minor amounts of various (open chain) intermediates were found to be present in the reaction mixture. Tin complexes were not observed. This might be due to the applied washing and precipitation methods (see experimental section). The largest ring structures were found when the longest α,ω-diol, i.e., 1,6-hexanediol, was used. The longer alkyl chain seems to facilitate the intramolecular transesterification, as well as to increase the solubility of the macrocycles, allowing for larger structures to form and stay in solution.

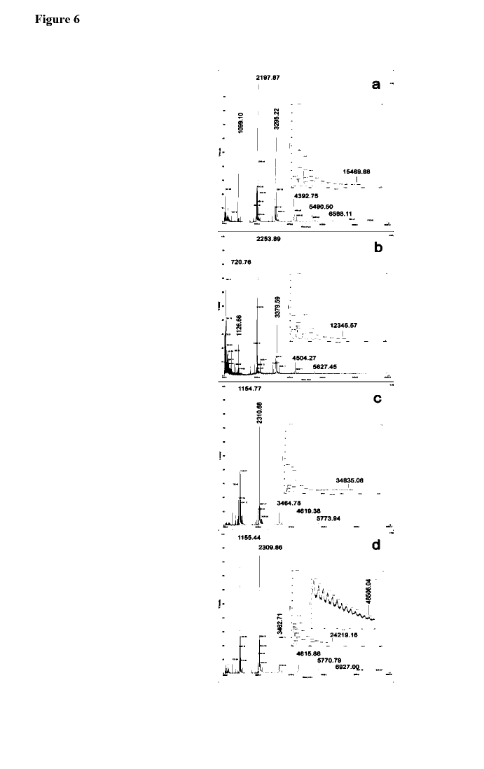

The MALDI-TOF spectra of the three types of pearl-necklace macrocycles, based on co-polymers of bis-PCBM with 1,2-ethanediol, 1,4-butanediol, and 1,6-hexanediol, respectively (i.e., n=1,2,3), are depicted in FIG. 6 (for full size spectra see S.I.). The structures and non-isotopic masses of the smallest macrocycles, up to a cycle containing five fullerene moieties, are depicted in FIG. 1. The MALDI-TOF spectra clearly show the strongly preferred formation of macrocycles up to the ones containing eight fullerene moieties (mass: 9234.97 amu.; FIG. 6d). Up to the cyclic 18-mer, the observed mass patterns match the simulated isotope distribution patterns, calculated for the cyclic structures, within experimental error. That is, for structures up to the 18-mers, it is clear that these are—at least in large majority—not the open linear chain polymers, because those structures would have a mass of 18 (H₂O) or 32 (MeOH) units higher.

In the insets of FIGS. 6a-d, the MALDI-TOF spectra have been enlarged in the highest mass regions. Even though we can not assign cyclic structures to these higher mass peaks with certainty, it does illustrate that this method of cyclization/polymerization is highly effective, obtaining polymeric/cyclic fullerene structures with masses up to ˜48.500 containing at least 42 fullerene units.

Besides cyclic structures, mass peaks corresponding to structures of intermediate open compounds are also observed. These intermediates are mono- and di-esterified bis-PCBM as well as some open carboxylic acid compounds.¹⁵ However, the most intense signals are observed from macrocylic structures. We furthermore deduct from the differences in spectrum shown in FIGS. 6c and 6d that for obtaining high mass structures it is favourable to first synthesise the open bis-transesterified bis-PCBM (i.e., the α,ω-diol) and subsequently allow this to react with bis-PCBM (see scheme 3). Interestingly, spectrum in FIG. 6d does not show a mass signal of compound 3 (1272 amu), indicating full conversion. The mass signal of 1155, furthermore, proves that intramolecular esterification is taking place when DBTO is added to compound 3.

In conclusion, we have synthesized fullerene macrocycles which form true pearl-necklace macrocyclic structures. Since these structures are still soluble, hence solution processable, we envision that they are applicable in fullerene based molecular electronic applications. Such application research is currently under way.

### Experimental Section

MALDI-TOF measurements were performed on a Voyager-DE Pro apparatus. Spectra were calibrated with a calibration mixture of: dimer of α-cyano-4-hydroxycinnamic acid, bradikin, angiotensin, ACTH and insuline. As a matrix S₈ was used. The calibrated measurements were done for a range of 300 to 10.000 amu. Higher masses were detected by applying a low mass gate of 3500, filtering out low mass macrocycles.

All reagents and solvents were used as received or purified using standard procedures. Purified Bis-PCBM (2) was obtained as a gift from Solenne B V, Groningen, The Netherlands.

Typical procedure for ring formation: A 50 mL. flame dried three-necked flask was charged with bis-PCBM (2) (512 mg, 0.465 mmol) and o-dichlorobenzene (30 mL.) The resulting solution was degassed by three N₂/vacuum purges. Subsequently, 1,6-hexanediol (55 mg, 0.465 mmol) and DBTO (46.3 mg, 0.186 mmol, 0.4 eq.) were added. The mixture was stirred at 120° C. for one week. The resulting product mixture was precipitated with methanol and centrifuged, yielding a brown pellet. The pellet was washed repeatedly with toluene until the supernatant was colourless. The supernatant (toluene) layers were combined and dried in vacuo yielding 354 mg of macrocycles.

### Supporting Information

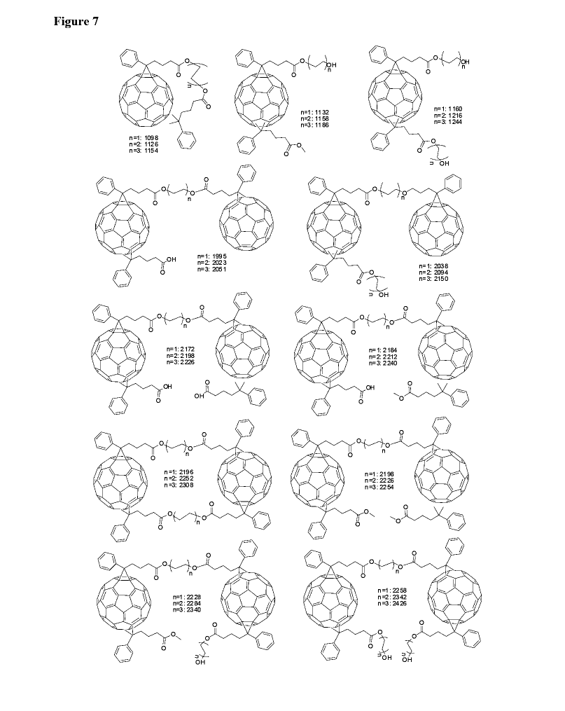

A list of intermediate structures with their masses (not corrected for isotope effects) are depicted in FIG. 7. Note that in the MALDI-TOF spectra often minor peaks corresponding to m/z+16, and sometimes +17, were observed. Since fullerenes are somewhat sensitive to oxygen, these minor mass peaks may stem from mono-oxidized structures. However, since the hypothetical linear (open) α-hydroxy-ω-carboxylic acids have a mass +18 (or +17, in case the signal is from the carboxylate anion) compared to the macrocyclic analogues, it cannot be ruled out that the signals originate from the open oligomers.

### REFERENCES CITED

¹ H. W. Kroto, J. R. Heath, S. C. O'Brien, R. F. Curl, R. E. Smalley, Nature 1985, 318, 162.
² T. Kawase, H. Kurata, Chem. Rev. 2006, 106, 5250.
³ L. Isaacs, P. Seiler, F. Diederich, Angew. Chem. Int. Ed. 1995, 1466.
⁴ A. Gradillas, J. Pérez-Castells, Angew. Chem. Int. Ed. 2006, 45, 6086.
⁵ S. E. Gibson, C. Lecci, Angew. Chem. Int. Ed. 2006, 45, 1364.
⁶ W. Zhang, J. S. Moore, Angew. Chem. Int. Ed. 2006, 45, 4416.
⁷ a) P. Anzenbacher Jr., R. Nishiyabu, M. A. Palacios, Coord. Chem. Rev. 2006, 250, 2929. b) M. Hoffmann, C. J. Wilson, B. Odell, H. L. Anderson, Angew. Chem. Int. Ed. 2007, 46, 3122.
⁸ K. Nakao, M. Nishimura, T. Tamachi, Y. Kuwatani, H. Miyasaka, T. Nishinaga, M. Niyoda, J. Amer. Chem. Soc. 2006, 128, 16740
⁹ a) H. R. Kricheldorf, M. Rabenstein, D. Langanke, G. Schwarz, M. Schmidt, M. Maskos, R-P. Krüger, High Perform. Polym. 2001, 13, 5123. b) H. R. Kricheldorf, G. Schwarz, Macromol. Rapid. Commun. 2003, 24, 359. c) X-F. Yuan, A. J. Masters, C. V. Nicholas, C. Booth, Makromol. Chem. 1988, 189, 823. d) M. Gordon, G. R. Scantlebury. J. Chem. Soc. B. 1967, 1.
¹⁰ a) R. C. Poller, S. P. Retout, J. Organometal. Chem. 1979,173, C7. b) J. Otera. Chem. Rev. 1993, 93, 1449.
¹¹ M.-F. Llauro, A. Michel, C. R. Chimie, 2006, 9, 1363
¹² P. Baumhof, R. Mazitschek, A. Giannis, Angew. Chem. Int. Ed., 2001, 40, 3672.
¹³ D. F. Kronholm, J. C. Hummelen and A. B. Sieval, USPATENT: US2005245606, 2005.
¹⁴ W. E. Wallace, C. M. Guttman, J. M. Antonucci, Polymer 41, 2219 2000.

### EXAMPLE 3

Bis[70]PCBM was also synthesized and prepared analogous to the procedure for [60]PCBM, and the 1^{st} reduction potential, which is directly proportional to the LUMO level, was measured by cyclic voltammetry. The table below shows the 1^{st} reduction potentials of [60]PCBM, bis-[60]PCBM, and bis-[70]PCBM, and it can be seen that the increase for the LUMO of bis[70]PCBM compared to [70]PCBM (the LUMO of which is almost identical to that of [60]PCBM), is about 100 meV, similar to the increase in LUMO of bis-[60]PCBM. Thus, increased performance in organic photodiodes can be expected for bis-[70]PCBM compared to [70]PCBM, and this has implications as well for mixtures of bis[60]PCBM and bis[70]PCBM; since the LUMOs are similar, they do not represent electron or hole traps for each other and may be used together in any proportion as semiconductors.

| CV 10 mv/s | red1 |
|---|---|
| [60]PCBM | −0.7345 |
| bis[60]PCBM | −0.8158 |
| bis[70]PCBM | −0.828 |

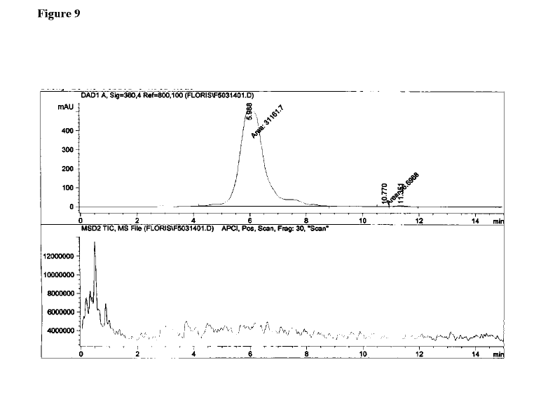

FIG. 9 is the HPLC spectrum of the bis-[70]PCBM used to obtain the above 1^{st} reduction potential. The levels of mono-adduct ([70]PCBM) and tris-adduct tris[70]PCBM are below 0.1% each.

### EXAMPLE 4

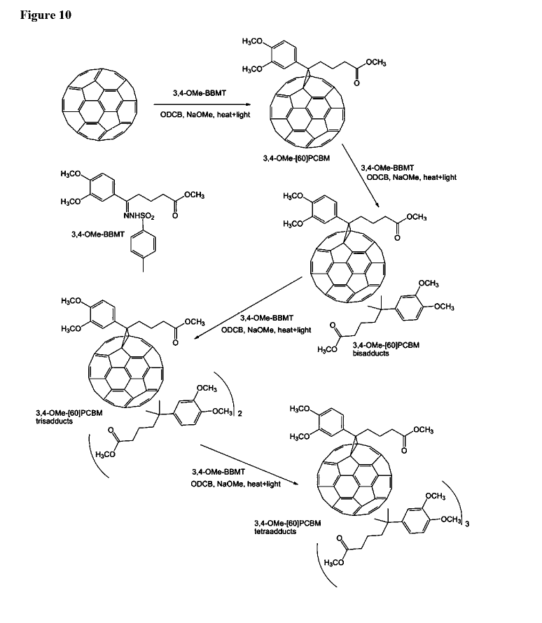

### Synthesis of 3,4-OMe-[60]PCBM monoadduct, and bis-, tris-, and tetra-adducts (See FIG. 10)

To 20.41 g of 3,4-OMe-BBMT in 1.5 L of o-dichlorobenzene under N₂ was added 2.55 g of sodium methoxide. The mixture was stirred for 20 min and 16.93 g of C₆₀ was added. The mixture was stirred for 30 min and then slowly heated to 95-100° C. After 2 h irradiation with a 400 W sodium lamp, the reaction proceeded at 100° C. overnight.

The reaction mixture was cooled down under illumination to <50° C. and concentrated in vacuo. Unreacted C₆₀ (309 mg) was isolated by column chromatography (silica gel, chlorobenzene/ethyl acetate 95:5 (v/v)). Mono-adduct and the mixture of bis-adducts were isolated using chlorobenzene/ethyl acetate 9:1 (v/v). Crude tris-adducts and tetra-adducts were isolated by further increasing the amount of ethyl acetate (up to 20 vol %).

The fractions containing pure mono-adduct were combined and concentrated in vacuo. The residue was redissolved in chlorobenzene and precipitated with methanol. The product was isolated on a filter and washed repeatedly with methanol and pentane. Drying in vacuo at 50° C. gave 5.52 g of the pure 3,4-OMe-[60]PCBM with spectroscopic properties as already reported in literature (F. B. Kooistra et al., Org. Lett. 2007, 551-554).

The bis-adducts were further purified by a second column chromatography (silica gel, toluene/ethyl acetate 9:1 (v/v)). The material was redissolved in chloroform, precipitated with methanol, and isolated and washed as described for the mono-adduct. This gave 10.52 g of the bis-adducts of 3,4-OMe-[60]PCBM.

The tris-adducts and tetra-adducts were purified by repetitive column chromatography (silica gel, toluene/ethyl acetate mixtures ranging from 5:1 to 3:1 (v/v)).They were isolated as described for the bis-adducts. Yields were 7.71 g of tris-adducts and 1.27 g of tetra-adducts of 3,4-OMe-[60]PCBM.

Bis-adducts: ¹H NMR (300 MHz, CDCl₃) δ 7.72-6.84 (br. m, 6H); 4.11-3.85 (m, 12H); 3.78-3.57 (m, 6H); 3.18-1.94 (br. m, 12H) ppm. IR (KBr, cm⁻¹): 2994; 2947; 2833; 2329; 1737; 1516; 1253; 1028; 527.

Tris-adducts: ¹H NMR (300 MHz, CDCl₃) δ 7.64-6.78 (br. m, 9H); 4.12-3.78 (m, 18H); 3.78-3.54 (m, 9H); 3.10-1.80 (br. m, 18H) ppm. IR (KBr, cm¹): 2948; 28335; 1737; 1516; 1253; 1027; 527.

Tetra-adducts: ¹H NMR (300 MHz, CDCl₃) δ 7.60-6.70 (br. m, 12H); 4.15-3.75 (m, 24H); 3.75-3.50 (m, 12H); 3.0-1.6 (br. m, 24H) ppm. IR (KBr, cm⁻¹): 2949; 2835; 1737; 1516; 1254; 1028; 526.

### EXAMPLE 5

### Synthesis of 3,4-OMe-[70]PCBM monoadduct and bisadducts

3,4-OMe-PCBM (as mixture of isomers) and the 3,4-OMe-[70]PCBM bis-adducts were synthesized using a procedure similar to that described for the corresponding [60]PCBM derivatives, with C₇₀ (6.73 g), NaOMe (650 mg) and 3,4-OMe-BBMT (5.22 g) as the starting materials. The yields were 4.03 g of the mono-adduct of 3,4-OMe-[70]PCBM and 3.45 g of the bis-adducts of 3,4-OMe-[70]PCBM. Higher adducts were observed in HPLC-MS but not isolated.

Mono-adduct: ¹H NMR (300 MHz, CDCl₃) δ 7.50-6.64 (br. m, 3H); 4.02, 3.96, 3.81, 3.75, 3.70, 3.69, and 3.52 (multiple singlets of various intensities, total 9H); 2.58-2.30 (m, 4H); 2.30-1.78 (m, 2H) ppm. IR (KBr, cm⁻¹): 2993; 2945; 2831; 1737; 1515; 1429; 1252; 1137; 1028; 795; 579; 534.

Bis-adducts: ¹H NMR (300 MHz, CDCl₃) δ 7.60-6.62 (br. m, 6H); 4.20-3.86 (m, 12H); 3.86-3.40 (m, 6H); 2.70-1.70 (br. m, 12H) ppm. IR (KBr, cm⁻¹): 2994; 2947; 2833; 1737; 1516; 1253; 1139; 1028; 535.

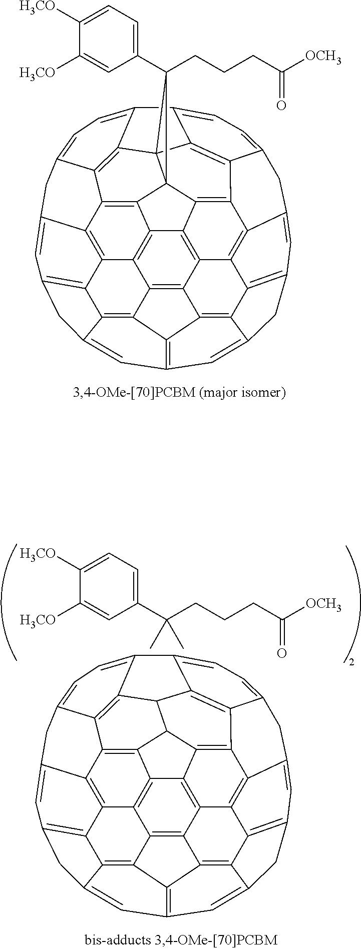

### EXAMPLE 6

### Synthesis of bis[60]PCB—C4

A mixture of 6.0 g of bis[60]PCBM, 0.683 mg of dibutyl tin oxide, 100 mL of o-dichlorobenzene, and 50 mL of 1-butanol was heated at 90° C. under N₂ for 25 h. The reaction was concentrated in vacuo and the product was isolated by column chromatography (silica gel, toluene). Precipitation and washing as usual gave 4.93 g of bis[60]PCB—C4 as fine dark brown powder. The ¹H NMR showed that ˜3 mol % of the mono-butyl-ester-mono-methyl ester bis-adducts was present.

¹H NMR (300 MHz, CDCl₃) δ 8.22-7.06 (br. m, 10H); 4.22-3.95 (m, 4H); 3.20-1.75 (br. m, 12H); 1.72-1.48 (m, 4H); 1.48-1.34 (m, 4H); 1.07-0.85 (m, 6H) ppm. IR (KBr, cm⁻¹): 3056; 2956; 2869; 2330; 1733; 1178; 1154; 700; 526.

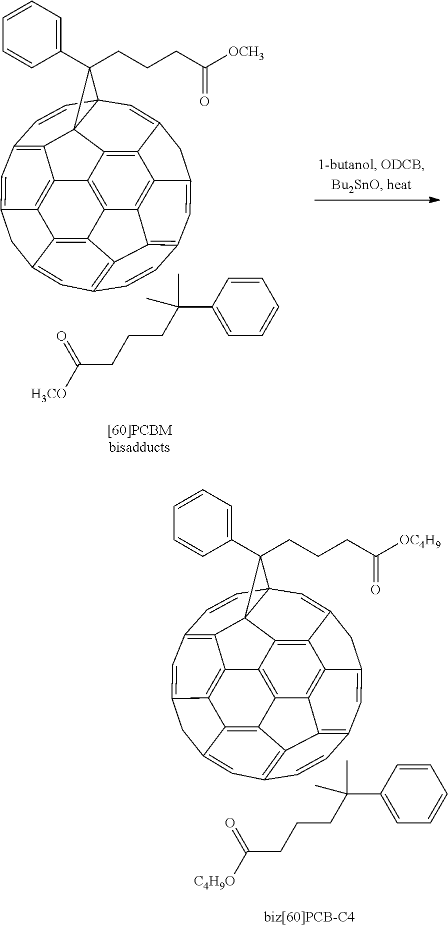

### EXAMPLE 7

### Synthesis of bis[60]PCB—C8

A mixture of 4.0 g of bis[60]PCBM, 0.460 mg of dibutyl tin oxide, 100 mL of o-dichlorobenzene, and 50 mL of 1-octanol was heated at 90° C. under N₂ for 2 days. The reaction mixture was concentrated in vacuo and the crude product isolated by column chromatography (silica gel, toluene). The crude product was further purified by column chromatography (silica gel, toluene). Precipitation and washing as usual gave 3.47 g of bis[60]PCB—C8 as a black solid.

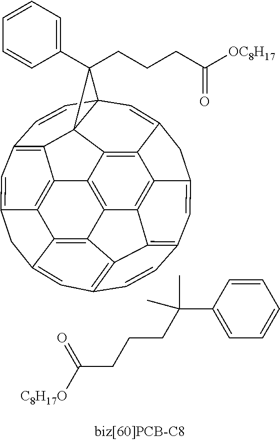

### EXAMPLE 8

### Synthesis of bis[70]PCB—C4

Bis[70]PCB—C4 was synthesized as described for bis[60]PCB—C4, using 3.20 g of bis[70]PCBM, 200 mg of dibutyltin oxide, 50 mL of o-dichlorobenzene and 25 mL of 1-butanol. Reaction time was two days. The overall yield was 2.88 g of black powder after isolation by centrifugation. The ¹H NMR showed that ˜2 mol % of the mono-butyl-ester-mono-methyl ester bis-adducts were present.

¹H NMR (300MHz, CDCl₃) δ 8.10-7.10 (br. m, 10H); 4.22-3.83 (m, 4H); 3.7-2.7 (br. m, 12H); 1.70-1.50 (m, 4H); 1.50-1.20 (m, 4H); 1.05-0.80 (m, 6H). IR (KBr, cm⁻¹): 2956; 2869; 1733; 1177; 700; 578; 535.

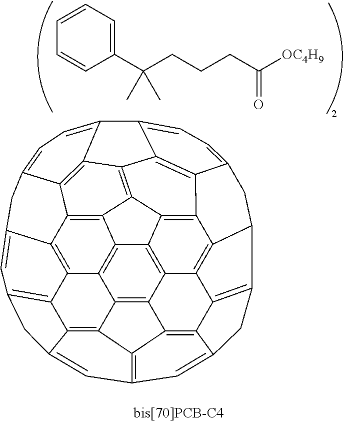

### EXAMPLE 9

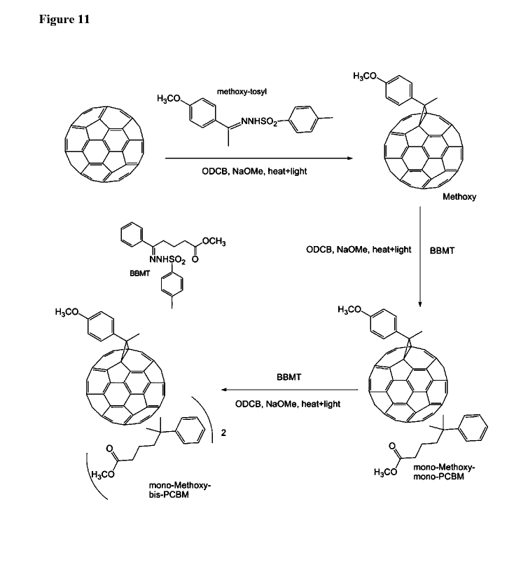

### Synthesis of the mixed methanofullerene compounds: mono-Methoxy-mono-PCBM and mono-Methoxy-bis-PCBM (See FIG. 11)

The required tosyl hydrazone, methoxy-tosyl, for the synthesis of Methoxy was prepared by reacting p-methoxyacetophenone and p-toluenesulfonyl hydrazide in methanol using standard procedures.

To 6.37 g of methoxy-tosyl in 1.5 L of o-dichlorobenzene (ODCB) under N₂ was added 1.08 g of NaOMe. After stirring for 10 min 14.4 g of C60 was added. After 10 min, the mixture was slowly heated to 95° C. and allowed to react overnight. The heating was turned off and the reaction mixture was illuminated with a 150 W sodium lamp while cooling down until HPLC showed full coversion to the [6,6]methanofullerene Methoxy. The reaction mixture was concentrated in vacuo. The pure Methoxy was obtained by repetitive column chromatography (silica gel, ODCB/heptane 1:1 (v/v)). The yield after precipitation, washing and drying was 8.18 g of Methoxy as a brown solid.

To a mixture of 3.38 g of BBMT and 490 mg of NaOMe in 600 mL of ODCB under N₂ was added 6.0 g of Methoxy. The resulting mixture was slowly heated to 95° C. After 4 h illumination was started with a 150 W sodium lamp, and the mixture was allowed to react at 95° C. overnight. The reaction mixture was cooled down under illumination to <50° C. and concentrated in vacuo. Column chromatography (silica gel, toluene, subsequently toluene/ethyl acetate 49:1 (v/v)) gave unreacted Methoxy (1.33 g) as well as a mixture of mono-Methoxy-mono-PCBM and mono-Methoxy-bis-PCBM. This mixture was further purified by a second column chromatography (silica gel; first toluene, then toluene/ethyl acetate 99:1 (v/v)) to give, after the usual precipitation, washing and drying, 3.73 g of mono-Methoxy-mono-PCBM and 1.63 g of mono-Methoxy-bis-PCBM.

Methoxy: ¹H NMR (300 MHz, CS₂/CDCl₃ (2:1 (v/v)) δ 7.85 (m, 2H); 7.04 (m, 2H); 3.90 (s, 3H); 2.54 (s, 3H) ppm. IR (KBr, cm⁻¹): 2997; 2975; 2924; 2832; 2328; 1608; 1513; 1427; 1249; 1028; 826; 626.

mono-Methoxy-mono-PCBM: ¹H NMR (300 MHz, CDCl₃) δ 8.18-6.98 (br. m, 9H); 3.99-3.80 (m, 3H); 3.76-3.57 (m, 3H); 3.18-1.90 (br. m, 9H) ppm. IR (KBr, cm⁻¹): 2947; 2833; 2330; 1738; 1513; 1249; 1174; 1034; 829; 700; 527.

mono-Methoxy-bis-PCBM: ¹H NMR (300 MHz, CDCl₃) δ 8.20-6.80 (br. m, 14H); 4.00-3.50 (br. m, 9H); 3.10-1.65 (br. m, 15H) ppm. IR (KBr, cm¹): 2947; 2835; 2332; 1738; 1514; 1249; 1174; 1034; 830; 700; 526.

### EXAMPLE 10

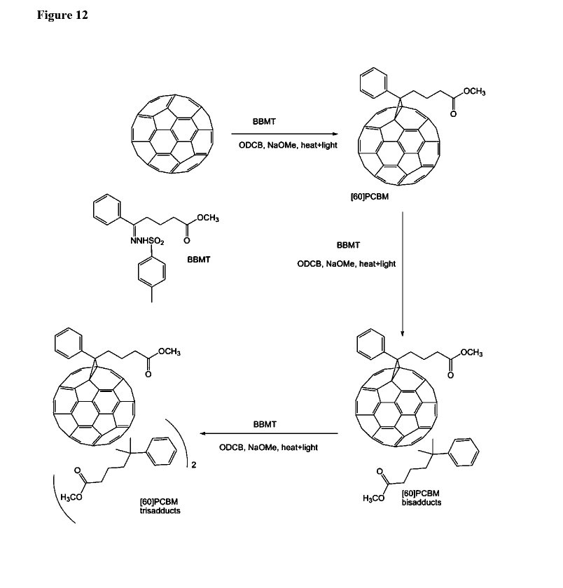

### [60]PCBM bis-adducts and tris-adducts. (See FIG. 12)

The synthesis of [60]PCBM bis- and tris-adducts was performed as described for the 3,4-OMe-PCBM multiadducts, but using BBMT as the reactant. The reaction mixture was separated into three fractions (column chromatography, silica gel): First, unreacted C₆₀ and crude [60]PCBM were isolated using 1,2,4-trimethylbenzene. Subsequently the mixture of bis-adducts and tris-adducts was isolated using toluene/ethyl acetate 3:1 (v/v). These were further separated on a second silica gel column, first using toluene as the eleunt to isolate the bis-adducts of [60]PCBM and subsequently toluene/ethyl acetate 19:1 (v/v) to isolated the tris-adducts of [60]PCBM.

### EXAMPLE 11

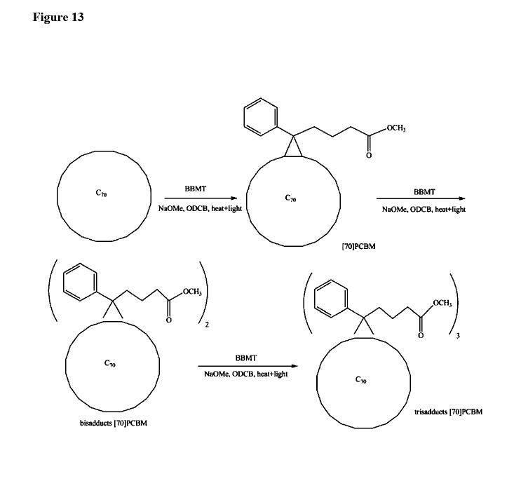

### [70]PCBM bis-adducts and tris-adducts. (See FIG. 13)

This synthesis of [70]PCBM bis-adducts and tris-adducts was performed as described for the [60]PCBM bis-adducts and tris-adducts, but using C₇₀ as the starting material instead of C₆₀. The mixture of bis-adducts and tris-adducts was isolated using toluene/ethyl acetate 9:1 (v/v) and separated into the bis-adducts of [70]PCBM and the tris-adducts of [70]PCBM by column chromatography on silica gel using toluene as the eluent.

Bis[70]PCBM was substituted for bis[60]PCBM in a solar cell as described in Example 1, and gave a similar VOC and power conversion efficiency as bis[60]PCBM.

### EXAMPLE 12

### CV and DPV Measurements: Initial Reduction Potentials

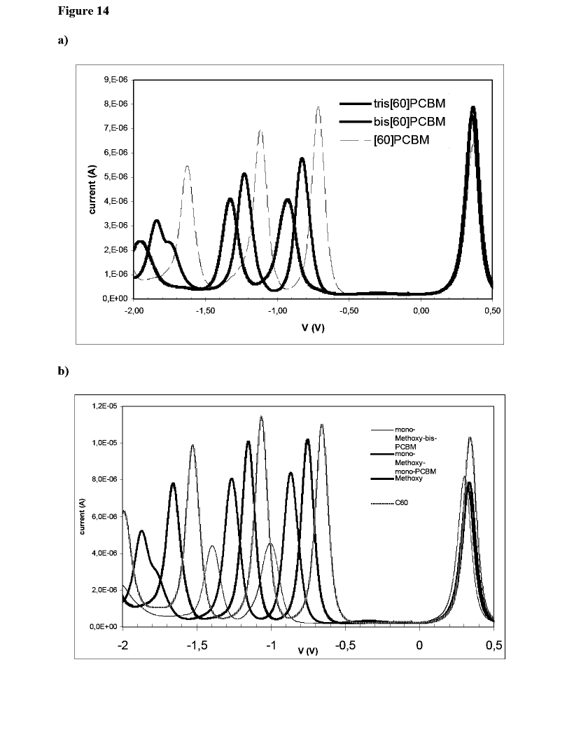

Cyclic voltammetry (CV) and differential pulse voltammetry (DPV) measurements were done to determine the initial reduction potentials of the methanofullerenes. The results are shown in FIGS. 14a-b. Details about the procedure can be found in literature (Kooistra et al, Organic Letters 2007, herein incorporated by reference). All compounds were measured against ferrocene as an internal standard and values using DPV measurements are listed in Table I below.

CV measurements showed that all reductions were reversible, including the 2^{nd} and 3^{rd} reduction of the methanofullerenes. The CV measurements showed the similar results, but with a somewhat lower accuracy. The initial reduction potentials provide a relative measure of the energy of the LUMO of the compounds. Initial reduction potential refers to the transfer of the first, or only, electron to the fullerene.

TABLE I
Initial reduction potentials determined using DPV measurements

| | Initial reduction potential |
|---|---|
| Compound | (all values +/− 10 mV) |
| [60]PCBM | −1.08 V |
| [70]PCBM | −1.09 V |
| Bis[60]PCBM | −1.19 V |
| Bis[60]PCB-C4 | −1.18 V |
| Bis-3,4-OMe-[60]PCBM | −1.19 V |
| Tris[60]PCBM | −1.29 V |
| Bis[70]PCBM | −1.20 V |
| C60 | −1.00 V |
| Methoxy | −1.09 V |
| Mono-methoxy-mono-PCBM | −1.19 V |
| Mono-methoxy-bis-PCBM | −1.30 V |

### EXAMPLE 13

The data provided in Table 1 of WO 2008/006071 (incorporated herein by reference) shows the effect of N-type impurities with different LUMO levels on the performance of bulk heterojunction organic photovoltaic devices. C60 is about 100 meV stronger as an acceptor than mono-adduct derivatives of C60, e.g., [60]PCBM, as can be seen in Example 12 above. Table 1 of WO 2008/006071 shows that impurity levels of up to about 2.5 mol % of C60 are tolerable; however, addition of C60 at 13 mol % with respect to the overall N-type composition reduces performance by more than 10% (i.e., from power conversion efficiency (PCE)=3.0 for mono-adduct [60]PCBM to PCE=2.6).

Fullerenes and fullerene derivatives that differ in adduct number by two or more differ in first reduction potential by about 200 meV or more as can be seen in Example 12 above; this effect is independent of the addend type. Table 1 of WO 2008/006071 shows that fullerene compound impurities which differ in the range of 200 meV to 300 meV from the main fullerene N-type component have much lower tolerance levels to preserve bulk heterojunction organic photovoltaic device performance: addition of 4 mol % of mono-adduct PCBM derivatives and ThCBM derivatives of C76, C78, and C84 (approximately in a ratio of C76/C78/C84=1/1/2), decreased device performance from PCE=4.1 to PCE=0.2 for ThCBMs, and PCE=3.9 to PCE=0.1.

Reed and Bolskar (Chem. Rev. 2000, 100, 1075-1120) describe the initial reduction potentials of C₇₆ (−0.83), C₇₈ (−0.72; −0.64), and C₈₄ (−0.67), or that each has between 150 meV and 300 meV stronger electron accepting ability than C60 or C70 which each have an initial reduction potential of about −0.98. The initial reduction potential of [84]PCBM has been measured at about 250 meV stronger electron acceptor than [60]PCBM. Based on this information, 4 mol % of a fullerene compound of about 150 meV-250 meV stronger electron accepting ability, or stronger, or 2 mol % of a fullerene compound of about 250 meV stronger electron accepting ability, or stronger, than the main N-type must be strictly avoided, and ideally, fullerene compounds of about 200 meV should be held to limits under 0.1 mol %-0.5 mol % for best performance.

Thus, in an N-type composition where the main N-type component has n adducts, the molar composition with respect to the N-type composition of compounds of adduct number of less than or equal to n−2 is 0 mol % to about 2 mol %, 0 mol % to about 0.5 mol %, or 0 mol % to about 0.1%; the molar composition of compounds of adduct number n−1 is 0 mol % to about 10 mol mol %, 0 mol % to about 5mol %, 0 mol % to about 2 mol %; and the molar composition of compounds greater than or equal to n+1 adducts is 0 mol % to 10% mol %; 0 mol % to about 5 mol %, 0 mol % to about 2 mol %, 0 mol % to about 0.5 mol %, or 0 mol % to about 0.1 mol %.

### EXAMPLE 14

Reaction of fullerenes with o-quinodimethanes is well known (Segura et al. Chem. Rev. 1999, 99, 3199-3246), giving Diels-Alder fullerene adducts. As is common in fullerene chemistry, bis, tris, and higher adducts are also formed, and can be separated, as described in Segura et al. Chem. Rev. 1999, 99, 3199-3246, on a silica gel column, or by HPLC using a typical column such as Buckyprep (Cosmocil) or 5-PBB (Cosmocil). Puplovskis et al. (Tetrahedron Lett. 1997, 38, 285) measured the first reduction potential of the mono-Diels-Alder descrived therein and found it to be 100 meV weaker electron acceptor compared to the parent C60, the same as the value found for mono-PCBM, therefore, the specifications given in this document for impurity levels of the different number adducts and other impurities apply. Frechet tested such Diels-Alder adducts in bulk heterojunction organic solar devices (MRS Spring meeting 2007 lecture Z1.4 (Symposium Z) on Apr. 10, 2007 “Optimizing Materials for Bulk heterojunction Polymer:Fullerene Photovoltaics”, by Kevin Sivula (presenting author), B. C. Thompson, S. A. Backer, D. F. Kavulak, J. M. J. Fréchet) and found performance on a par with [60]PCBM in combination with P3HT. A general reaction schematic is shown below for forming Diels-Alder and mixed Diels-Alder—methanofullerene comoounds. The Diels-Alder adducts can be either single regio-isomer (formed by synthesis techniques as described in Segura et al. Chem. Rev. 1999, 99, 3199-3246 or in Thilgen et al. “Spacer-Controlled Multiple Functionalization of Fullerenes,” Topics in Current Chemistry (2004) 248: 1-61, Springer-Verlag Berlin Heidelberg) or mixtures of multiple regio-isomers. Compositions of Diels-Alder fullerene derivative compounds formed by o-quinodimethane addition reaction and mixed Diels-Alder—methnoafullerene or other addend type compounds can be used, for example, in compositions as follows:

The main component is for example one of the following: bis-Diels-Alder; tris-Diels-Alder; tetrakis-Diels-Alder; mono-Diels-Alder-mono-methanofullerene; mono-Diels-Alder-bis-methanofullerene; bis-Diels-Alder-mono-methanofullerene; mono-Diels-Alder-tris-methanofullerene; bis-Diels-Alder-bis-methanofullerene; tris-Diels-Alder-mono-methanofullerene, where the n−1 adduct is 0 mol % to about 10 mol % with respect to the fullerene composition, 0 mol % to about 5 mol %, or 0 mol % to about 1 mol %; adducts of less than or equal to n−2 are 0 mol % to about 2 mol % cumulatively with respect to the fullerene composition, 0 mol % to about 0.5 mol %, or 0 mol % to about 0.1 mol %; and the adducts that are greater than or equal to n+1 are 0 mol % to about 10% cumulatively with respect to the fullerene composition.

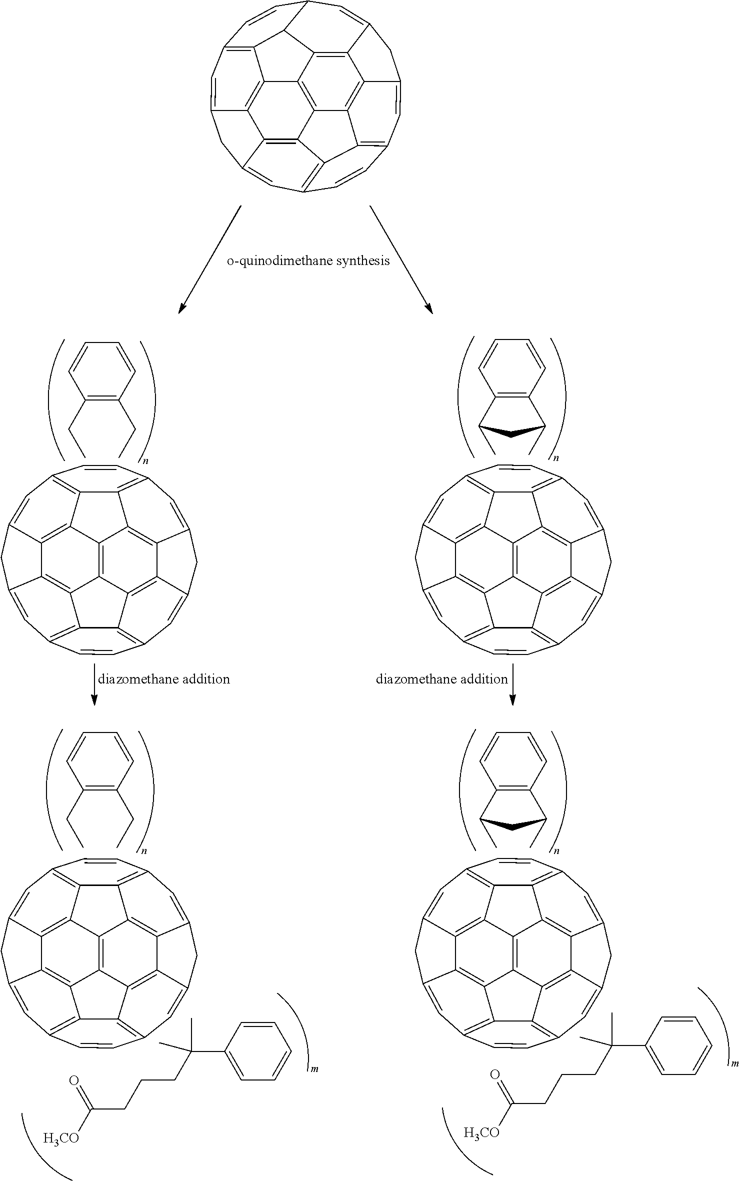

### EXAMPLE 15

An alternate example of a mixed fullerene multi-adduct is synthesis first of a bis-PCBM as in Example 1 (at purity levels of n−1 and n−2 adducts as specified), and then substitution of this bis-PCBM for C60 and following any procedure given in Segura et al. (Chem. Rev. 1999, 99, 3199-3246) for o-quinodemathane+fullerene synthesis to give the mixed bis-PCBM, mono-Diels-Alder C60 tris-adduct. The mixture is purified by a silica gel column or HPLC using a typical column such as Buckyprep (Cosmocil) or 5-PBB (Cosmocil) to >99 mol %, so that C60, mono-adduct of PCBM, and bis-adduct of PCBM, and tetra-adducts are cumulatively less than 1 mol %. This procedure can be followed for C60, C70, and other fullerenes. Such mixed multi-adducts allow for a much greatly enhanced efficiency for the o-quinodimethane reactions, as bis-PCBM is almost 100× more soluble in o-dichlorobenzene than C60. This allows as well for more efficient separations.

### EXAMPLE 16

An alternate example of a mixed fullerene multi-adduct is synthesis first of a mono-PCBM as described in Hummelen et al. (J. Org. Chem.1995, 60, 532-538) (at purity levels of n−1 and n−2 adducts as specified), and then substitution of this bis-PCBM for C60 and following any procedure given in Segura et al. (Chem. Rev. 1999, 99, 3199-3246) for o-quinodemathane+fullerene synthesis to give the mixed bis-PCBM, mono-Diels-Alder C60 tris-adduct. The mixture is purified by a silica gel column or HPLC using a typical column such as Buckyprep (Cosmocil) or 5-PBB (Cosmocil) to >99 mol %, so that C60, mono-adduct of PCBM, and bis-adduct of PCBM, and tetra-adducts are cumulatively less than 1 mol %. This procedure can be followed for C60, C70, and other fullerenes. Such mixed multi-adducts allow for enhanced efficiency for the o-quinodimethane reactions, as mono-PCBM is about 10× more soluble in o-dichlorobenzene than C60. This allows as well for more efficient separations.

### EXAMPLE 17

In typical fullerene addition syntheses of multi-adducts, multiple regio-isomers are formed. It can be advantageous in certain circumstances to have compositions such as described herein in the form of a reduced number of regio-isomers or single regio-isomers. The LUMO of individual regio-isomers can differ (for example, see Nierengarten et al., HELVETIC CHIMICA ACTA Vol. 80 (1997). p. 2238.) and electron mobility can be reduced for a mixture of regio-isomers compared to a smaller number of regio-isomers or single regio-isomer based on the tendency of a regio-isomer mixture to form less crystalline structures compared to a mixture with less regio-isomers and based on a higher degree of disorder.

TLC and HPLC trials (silica, toluene or toluene/cyclohexane mixtures) demonstrated that the mixture of bis-adducts as obtained from the synthesis of bis[60]PCB-C4 could be separated into fractions, each containing only a limited number of the total amount of isomers present. Therefore, 1 g of the bis[60]PCB—C4 mixture was separated into two fractions (column chromatography, silica gel, toluene). These were isolated as usual and investigated by HPLC and CV. Part 1 (the first fraction to elute) was 515 mg, part 2 was 355 mg of material. CV results are listed in the Table II below.

TABLE II
CV Results

| Isomer Fraction | Initial Reduction Potential |
|---|---|
| Bis[60]PCB-C4 mixture | −1.17 V |
| Bis[60]PCB-C4 Part 1 | −1.17 V |
| Bis[60]PCB-C4 Part 2 | −1.18 V |

As can be seen, the isomer fractions have different overall reduction potentials. Further fractionation can give fractions with significantly different reductions potentials than the overall mixture of isomers. Preparatory-scale HPLC with a silica gel column can also be used to prepare larger quantities.

### Synthesis of tethered bis-adduct

Techniques are well-known in the art to construct single-isomer multi-adduct fullerene derivatives. For example see Thilgen et al., “Spacer-Controlled Multiple Functionalization of Fullerenes,” Topics in Current Chemistry (2004) 248: 1-61, Springer-Verlag Berlin Heidelberg for an overview of such techniques, incorporated herein by reference in its entirety. Single isomer bis, tris, and higher adducts are useful since electron mobility of single isomer compounds can be larger due to higher degrees of crystallinity and less disorder in the N-type domains in the organic electronics device, such as an organic photodiode. In some tethered multi-adduct reactions, more than one isomer can be formed, such as 2 or 3 regio-isomer forms, and these may be advantageous to a mixture containing a larger number of regio-isomers for the reasons stated above.

### Incorporation by Reference

All of the patents and published patent applications cited herein are hereby incorporated by reference.

### Equivalents

Those skilled in the art will recognize, or be able to ascertain using no more than routine experimentation, many equivalents to the specific embodiments of the invention described herein. Such equivalents are intended to be encompassed by the following claims.

1-174. (canceled)

175. A composition, comprising:
one or more fullerene derivatives, wherein:
each fullerene derivative bears exactly n addends;
n is independently greater than or equal to 2;
the derivatized fullerenes are independently C60, C70, C76, C78, C84 or C90;
the fullerene derivative present in the largest mol % has a first initial reduction potential;
the combined amount of fullerene derivatives with a second initial reduction potential between about 50 meV and 150 meV greater than the first initial reduction potential is 0 mol % to about 5 mol %;
the combined amount of fullerene derivatives with a third initial reduction potential between 150 meV and about 250 meV greater than the first initial reduction potential is 0 mol % to about 2 mol %; and
the combined amount of fullerene derivatives with a fourth initial reduction potential at least about 100 meV less than the first initial reduction potential is 0 mol % to about 10 mol %.

176. The composition of claim 175, wherein the derivatized fullerene is C60 or C70.

177. The composition of claim 175, wherein the derivatized fullerene is C60.

178. The composition of claim 175, wherein the derivatized fullerene is C70.

179. The composition of claim 175, wherein the combined amount of fullerene derivatives with a second initial reduction potential between about 50 meV and 150 meV greater than the first initial reduction potential is 0 mol % to about 2 mol %.

180. The composition of claim 175, wherein the combined amount of fullerene derivatives with a second initial reduction potential between about 50 meV and 150 meV greater than the first initial reduction potential is 0 mol % to about 0.5 mol %.

181. The composition of claim 175, wherein the combined amount of fullerene derivatives with a second initial reduction potential between about 50 meV and 150 meV greater than the first initial reduction potential is 0 mol % to about 0.1 mol %.

182. The composition of claim 175, wherein the combined amount of fullerene derivatives with a third initial reduction potential between 150 meV and about 250 meV greater than the first initial reduction potential is 0 mol % to about 0.5 mol %.

183. The composition of claim 175, wherein the combined amount of fullerene derivatives with a third initial reduction potential between 150 meV and about 250 meV greater than the first initial reduction potential is 0 mol % to about 0.1 mol %.

184. The composition of claim 175, wherein the combined amount of fullerene derivatives with a fourth initial reduction potential at least about 100 meV less than the first initial reduction potential is 0 mol % to about 5 mol %.

185. The composition of claim 175, wherein the combined amount of fullerene derivatives with a fourth initial reduction potential at least about 100 meV less than the first initial reduction potential is 0 mol % to about 2 mol %.

186. The composition of claim 175, wherein the combined amount of fullerene derivatives with a fourth initial reduction potential at least about 100 meV less than the first initial reduction potential is 0 mol % to about 0.5 mol %.

187. The composition of claim 175, wherein the combined amount of fullerene derivatives with a fourth initial reduction potential at least about 100 meV less than the first initial reduction potential is 0 mol % to about 0.1 mol %.

188. A composition, comprising:
one or more fullerene derivatives, wherein:
the fullerene derivative present in the largest mol % bears exactly n addends;
n is independently greater than or equal to 2;
the derivatized fullerenes are independently C60, C70, C76, C78, C84 or C90;
the combined amount of fullerene derivatives with less than or equal to n−2 addends is 0 mol % to about 2 mol %;
the combined amount of fullerene derivatives with n−1 addends is 0 mol % to about 5 mol %; and
the combined amount of fullerene derivatives with greater than or equal to n+1 addends is 0 mol % to about 10 mol %.

189. The composition of claim 188, wherein the derivatized fullerene is C60 or C70.

190. The composition of claim 188, wherein the derivatized fullerene is C60.

191. The composition of claim 188, wherein the derivatized fullerene is C70.

192. The composition of claim 188, the combined amount of fullerene derivatives with less than or equal to n−2 addends is 0 mol % to about 0.5 mol %.

193. The composition of claim 188, the combined amount of fullerene derivatives with less than or equal to n−2 addends is 0 mol % to about 0.1 mol %.

194. The composition of claim 188, the combined amount of fullerene derivatives with n−1 addends is 0 mol % to about 2 mol %.

195. The composition of claim 188, the combined amount of fullerene derivatives with n−1 addends is 0 mol % to about 0.5 mol %.

196. The composition of claim 188, the combined amount of fullerene derivatives with n−1 addends is 0 mol % to about 0.1 mol %.

197. The composition of claim 188, the combined amount of fullerene derivatives with greater than or equal to n+1 addends is 0 mol % to about 5 mol %.

198. The composition of claim 188, the combined amount of fullerene derivatives with greater than or equal to n+1 addends is 0 mol % to about 2 mol %.

199. The composition of claim 188, the combined amount of fullerene derivatives with greater than or equal to n+1 addends is 0 mol % to about 0.5 mol %.

200. The composition of claim 188, the combined amount of fullerene derivatives with greater than or equal to n+1 addends is 0 mol % to about 0.1 mol %.

201. The composition of claim 175, wherein the fullerene derivative present in the largest mol % consists of a single regio-isomer.

202. The composition of claim 175, wherein the fullerene derivative present in the largest mol % consists of less than or equal to three regio-isomers.

203. The composition of claim 175, wherein the fullerene derivative present in the largest mol % consists of less than or equal to six regio-isomers.

204. The composition of claim 175, wherein the fullerene derivative present in the largest mol % consists of less than or equal to nine regio-isomers.

205. The composition of claim 175, wherein the fullerene derivative present in the largest mol % consists of less than or equal to twelve regio-isomers.

206. The composition of claim 175, wherein the fullerene is a fullerene dimer.

207. The composition of claim 175, wherein the fullerene is a endohedral fullerene.

208. Use of the composition of claim 175 as an N-type semiconductor in an organic electronics application.

209. A photodiode, comprising a composition of claim 175.

210. A photovoltaic device, comprising a composition of claim 175.
